(19) United States
(12) Patent Application Publication
(10) Pub. No.: US 2011/0008974 A1
(43) Pub. Date: Jan. 13, 2011

(54) CIRCUIT DESIGN ASSEMBLIES

(76) Inventor: IOAN ALEXANDRU SALOMIE, Kamuela, HI (US)

Correspondence Address: JENSEN & PUNTIGAM, P.S., 2033 SIXTH AVENUE, SUITE 1020, SEATTLE, WA, 98121-2527, US

(21) Appl. No.: 12/501,408

(22) Filed: Jul. 11, 2009

(51) Int. Cl. H01R 12/00; G06F 17/50; H05K 3/00

(52) U.S. Cl. 439/55; 29/829; 716/139; 716/104

(57) ABSTRACT

Circuit design assemblies, referred to herein as a “SpinBoard” and “SpinConnector” assemblies, are disclosed. The assemblies may include any of a variety of advantageous structures, including for example a board with a grid defining circuit point positions, and SpinConnector structures for building circuits. The disclosed SpinConnector structures may include advantageous features such as pin and plate structures that allow building fixed or articulating connector chains, and improved contact structures for conductive contact with electronic components. Software for designing the provided assemblies is also disclosed.

### BACKGROUND

Current technologies provide means for prototyping using breadboards and Printed Circuit Boards (PCBs). PCBs provide conductive pathways, or traces, which are traditionally etched from copper sheets laminated onto a non-conductive board. The traces on PCBs can be designed specifically for a particular electronic circuit or, for prototyping purposes, PCBs may have a generic layout. However, PCBs are not flexible when customizable electronic circuits are needed. Replacing electronic components on a PCB may require unsoldering and removing a previous component, then soldering a new component onto the PCB.

Solderless breadboards are described in the patents U.S. Pat. No. 6,685,483 (Blauvelt), U.S. Pat. No. 7,273,377 (Seymour), U.S. Pat. No. 6,916,211 (Price), US 2004/0096812 (Goh). Solderless breadboards provide more flexibility than PCBs when prototyping or when customizable electronic circuits are needed. Yet existing breadboard designs have some limitations. For example, existing breadboards often exhibit strong parasitic influence between neighboring non-connected circuits, in part due to their fixed distribution of current flow in rows and columns. Such neighboring circuits may be prone to oscillations and mutual influences, and as a result are not very well suited for experimenting with high frequency electronic circuits. Also, existing breadboards are often designed for low to medium power circuits and cannot endure higher currents. Furthermore, existing breadboards may not allow for soldering some or all of the electronic components in place when a circuit is considered to be finalized.

### SUMMARY

Circuit design assemblies, referred to herein as “SpinBoard” and “SpinConnector” assemblies, are disclosed. The disclosed assemblies may include any of a variety of advantageous structures disclosed herein, including for example a board with grid defining circuit point positions, and SpinConnector structures for building circuits with or without such board. The disclosed SpinConnector structures may include advantageous features such as pin and plate structures that allow building fixed or articulating connector chains, and improved contact structures for conductive contact with electronic components. A computing device equipped with software for designing assemblies in accordance with this disclosure is also described. Additional aspects and embodiments are disclosed in detail below.

### BRIEF DESCRIPTION OF THE DRAWINGS

The foregoing and other features of the present disclosure will become more fully apparent from the accompanying drawings. These drawings depict several embodiments in accordance with the disclosure and are not to be considered limiting of its scope. In the drawings:

FIG. 1 illustrates a perforated board with a triangle based aperture distribution.

FIG. 2 illustrates a perforated board with a quadrilateral aperture distribution.

FIG. 3A illustrates a top view of a SpinConnector.

FIG. 3B illustrates a cross section view of a SpinConnector.

FIG. 3C illustrates a side view of a SpinConnector.

FIG. 4A illustrates a top view of a SpinConnector fitted with a contact element.

FIG. 4B illustrates a cross section view of a SpinConnector fitted with a contact element.

FIG. 5A illustrates a top view of a SpinConnector fitted with a contact element and comprising a cap hole.

FIG. 5B illustrates a cross section view of a SpinConnector fitted with a contact element and comprising a cap hole.

FIG. 6A illustrates a cross section view of a SpinConnector fitted with multiple contact elements.

FIG. 6B illustrates a cross section view of a SpinConnector fitted with a small contact element.

FIG. 6C illustrates a cross section view of a SpinConnector fitted with differently sized contact elements.

FIG. 7 illustrates a cross section view of SpinConnectors linked together by a pin inserted into pin receptacles of multiple plates.

FIG. 8 illustrates a cross section view of a three pin SpinConnector.

FIG. 9 illustrates a cross section view of a SpinBoard assembly comprising a three pin SpinConnector inserted into a perforated board.

FIG. 10 illustrates a cross section view of an example SpinBoard assembly.

FIG. 11 illustrates a cross section view of an example SpinBoard assembly comprising a single-pin SpinConnector.

FIG. 12 illustrates a cross section view of an example SpinBoard assembly.

FIG. 13 illustrates a cross section view of an example SpinBoard assembly.

FIG. 14A illustrates a cross section view of a SpinConnector with contact element in a first stage of assembly.

FIG. 14B illustrates a cross section view of a SpinConnector with contact element in a second stage of assembly.

FIG. 14C illustrates a cross section view of a SpinConnector with assembled contact element in place.

FIG. 15A illustrates a side view of an example contact element.

FIG. 15B illustrates two top views of an example contact element.

FIG. 15C illustrates two top views of an example contact element.

FIG. 16A illustrates a cross section view of an example SpinBoard assembly in a first stage.

FIG. 16B illustrates a cross section view of an example SpinBoard assembly in a second stage.

FIG. 17A illustrates a cross section view of an example SpinConnector with a jack, internal cavity, and contact element.

FIG. 17B illustrates a cross section view of an example SpinConnector with a jack and internal cavity.

FIG. 17C illustrates across section view of an example SpinConnector with a jack and solder pad.

FIG. 18 illustrates a cross section view of an example SpinBoard assembly.

FIG. 19 illustrates an example pin adapted for multilayer SpinBoard embodiments.

FIG. 20 illustrates an example multilayer SpinBoard embodiment and example pins adapted for such embodiment.

FIG. 21 illustrates top views of various example three pin SpinConnectors.

FIG. 22 illustrates top views of various example five pin SpinConnectors.

FIG. 23 illustrates top views of various example four pin SpinConnectors.

FIG. 24 illustrates top views of various example expanded cap type SpinConnectors.

FIG. 25A illustrates a top view of an example transistor.

FIG. 25B illustrates a side view of an example transistor.

FIG. 26A illustrates a top view of an example capacitor.

FIG. 26B illustrates a side view of an example capacitor.

FIG. 27A illustrates a top view of an example LED.

FIG. 27B illustrates a side view of an example LED.

FIG. 28A illustrates a first side view of an example resistor.

FIG. 28B illustrates a second side view of an example resistor.

FIG. 29A illustrates a top view of an example Integrated Circuit (IC).

FIG. 29B illustrates a side view of an example IC.

FIG. 29C illustrates a second side view (front view) of an example IC.

FIG. 30 illustrates an example circuit schema.

FIG. 31 illustrates an example circuit schema.

FIG. 32 illustrates an example circuit schema.

FIG. 33 illustrates an example circuit schema.

FIG. 34A illustrates a view of an example SpinBoard assembly showing all elements as may be disposed on either surface of a perforated board.

FIG. 34B illustrates an example top view of a SpinBoard assembly, with certain elements removed to better illustrate the remaining elements.

FIG. 34C illustrates an example bottom view of a SpinBoard assembly.

FIG. 35A illustrates a view of an example SpinBoard assembly showing all elements as may be disposed on either surface of a perforated board.

FIG. 35B illustrates an example top view of a SpinBoard assembly, with certain elements removed to better illustrate the remaining elements.

FIG. 35C illustrates an example bottom view of a SpinBoard assembly.

FIG. 36A illustrates a top view of an example SpinConnector assembly.

FIG. 36B illustrates a top view of an example SpinConnector assembly with certain elements removed to better illustrate the remaining elements.

FIG. 36C illustrates a top view of an example reshaped SpinConnector assembly.

FIG. 37A illustrates a view of an example SpinBoard assembly showing all elements as may be disposed on either surface of a perforated board.

FIG. 37B illustrates an example top view of a SpinBoard assembly, with certain elements removed to better illustrate the remaining elements.

FIG. 37C illustrates an example top view of a SpinBoard assembly, with certain elements removed to better illustrate the remaining elements.

FIG. 37D illustrates an example bottom view of a SpinBoard assembly.

FIG. 38A illustrates an example top view of a SpinConnector.

FIG. 38B illustrates an example top view of a SpinConnector.

FIG. 38C illustrates an example top view of an isolation sheet.

FIG. 38D illustrates an example transparent top view of SpinConnectors separated by an isolation sheet.

FIG. 38E illustrates an example top view of a SpinBoard assembly with isolation sheets.

FIG. 39A illustrates a view of an example SpinBoard assembly showing all elements as may be disposed on either surface of a perforated board.

FIG. 39B illustrates an example top view of a SpinBoard assembly, with certain elements removed to better illustrate the remaining elements.

FIG. 39C illustrates an example top view of a SpinBoard assembly, with certain elements removed to better illustrate the remaining elements.

FIG. 39D illustrates an example bottom view of a SpinBoard assembly.

FIG. 40A illustrates an example SpinBoard assembly.

FIG. 40B illustrates an example view of a non-planar SpinBoard assembly.

FIG. 40C illustrates an example view of a non-planar SpinBoard assembly.

FIG. 41A illustrates a view of an example SpinBoard assembly showing all elements as may be disposed on either surface of a perforated board.

FIG. 41B illustrates an example top view of a SpinBoard assembly, with certain elements removed to better illustrate the remaining elements.

FIG. 41C illustrates an example bottom view of a SpinBoard assembly.

FIG. 42A illustrates a view of an example SpinBoard assembly showing all elements as may be disposed on either surface of a perforated board.

FIG. 42B illustrates an example top view of a SpinBoard assembly, with certain elements removed to better illustrate the remaining elements.

FIG. 42C illustrates an example bottom view of a SpinBoard assembly.

FIG. 43A illustrates a view of an example SpinBoard assembly showing all elements as may be disposed on either surface of a perforated board.

FIG. 43B illustrates an example top view of a SpinBoard assembly, with certain elements removed to better illustrate the remaining elements.

FIG. 43C illustrates an example bottom view of a SpinBoard assembly.

FIG. 44A illustrates a view of an example SpinBoard assembly showing all elements as may be disposed on either surface of a perforated board.

FIG. 44B illustrates an example top view of a SpinBoard assembly, with certain elements removed to better illustrate the remaining elements.

FIG. 44C illustrates an example bottom view of a SpinBoard assembly.

FIG. 45A illustrates a view of an example SpinBoard assembly showing all elements as may be disposed on either surface of a perforated board.

FIG. 45B illustrates an example top view of a SpinBoard assembly, with certain elements removed to better illustrate the remaining elements.

FIG. 45C illustrates an example bottom view of a SpinBoard assembly.

FIG. 46A illustrates a view of an example SpinBoard assembly showing all elements as may be disposed on either surface of a perforated board.

FIG. 46B illustrates an example top view of a SpinBoard assembly, with certain elements removed to better illustrate the remaining elements.

FIG. 46C illustrates an example bottom view of a SpinBoard assembly.

FIG. 46D illustrates a SpinBoard assembly with certain elements removed to better illustrate the remaining elements.

FIG. 46E illustrates an example middle layer of a multilayer SpinBoard assembly.

FIG. 46F illustrates an example top and/or bottom layer of a multilayer SpinBoard assembly.

FIG. 46G illustrates an example cross section of a multilayer SpinBoard assembly.

FIG. 46H illustrates a view of an example SpinBoard assembly showing the plates, pins and perforated board.

FIG. 46I illustrates a view of an example SpinBoard assembly showing the plates, pins and perforated board.

FIG. 47A illustrates an example top view of a plate with conductive pad and pin extension.

FIG. 47B illustrates an example side view of a plate with conductive pad and pin extension.

FIG. 48A illustrates an example top view of a plate with conductive pad, conductive receptacle and pin extensions.

FIG. 48B illustrates an example cross section of a plate with conductive pad, conductive receptacle and pin extensions.

FIG. 48C illustrates an example side view of a plate with conductive pad, conductive receptacle and pin extensions.

FIG. 49A illustrates an example top view of a plate with conductive pad, conductive jack and pin extensions.

FIG. 49B illustrates an example side view of a plate with conductive pad, conductive jack and pin extensions.

FIG. 50A illustrates an example top view of a plate with conductive pads and pin extensions.

FIG. 50B illustrates an example side view of a plate with conductive pads and pin extensions.

FIG. 51 illustrates an example top view of a SpinBoard assembly.

FIG. 52 illustrates an example top view of a SpinBoard assembly.

FIG. 53A illustrates an example top view of a SpinBoard assembly.

FIG. 53B illustrates an example top view of a SpinBoard assembly, with certain elements removed to better illustrate the remaining elements.

FIG. 53C illustrates an example top view of a SpinBoard assembly, with certain elements removed to better illustrate the remaining elements.

FIG. 54A illustrates an example top view of a SpinBoard assembly.

FIG. 54B illustrates an example top view of a SpinBoard assembly, with certain elements removed to better illustrate the remaining elements.

FIG. 54C illustrates an example top view of a SpinBoard assembly, with certain elements removed to better illustrate the remaining elements.

FIG. 55 illustrates an example top view of a SpinBoard assembly.

FIG. 56 illustrates an example computing device, computer readable medium and method for designing a SpinBoard or SpinConnector assembly.

FIG. 57 illustrates an overview of various example assembly configuration options.

FIG. 58 illustrates an overview of various example applications for technologies disclosed herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the drawings, may be arranged, substituted, combined, and designed in a wide variety of different configurations, all of which are explicitly contemplated and made part of this disclosure.

The term “SpinBoard” is used herein to refer to a circuit design board assembly. The SpinBoard assembly may include a board, “SpinConnectors”, and electronic components. SpinConnectors may comprise, for example, conductive pin and plate structures as discussed below. SpinConnector assemblies, not requiring a board, are also described herein. Electronic components may comprise, for example, any component for use with an electric circuit. Electronic components may include components making use of any conductivity type, including for example, electric, thermal, optical, wireless, or magnetic conductivity. Electronic components may include, without limitation, passive components such as resistors, capacitors, and coils, and semiconductor components such as diodes, Light Emitting Diodes (LEDs), integrated circuits, and transistors.

SpinBoard and SpinConnector assemblies can be adapted to suit a wide variety of applications, as described in further detail herein. For example, some embodiments may be suited for hobby and prototyping, teaching and training, small scale, and industrial electronic applications. Some embodiments may be advantageously adapted to use as reconfigurable LED bulbs. Further embodiments may be configured to produce structures similar to printed circuit boards, however with certain advantages over printed circuit boards, for example, SpinBoard and SpinConnector assemblies need not use toxic chemical procedures involved in etching printed circuit boards. SpinBoard and SpinConnector manufacture may instead use an assembly step integrated into the production line.

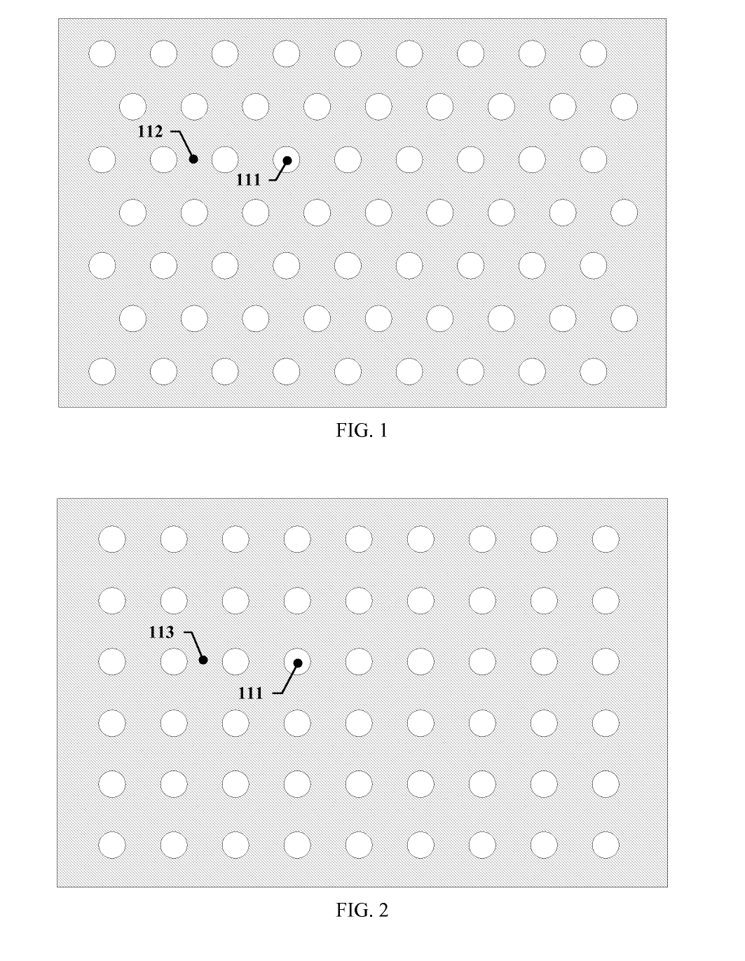

FIG. 1 and FIG. 2 illustrate various example perforated boards 112 and 113, each comprising a plurality of apertures such as 111. In some embodiments, a perforated board 112 or 113 may be made of an insulating, flat, rigid material, such as hard plastic. In some embodiments, a perforated board 112 or 113 may be shaped to any desired shape, for example as a dome shape which may allow assembly of a configurable LED bulb which may serve for example as an overhead light for a room. A perforated board 112 or 113 may also be made of flexible material such as supple plastic or rubber. A perforated board 112 or 113 may also be opaque or transparent. A perforated board 112 or 113 may comprise multiple layers as discussed further herein. A perforated board 112 or 113 may include any number of apertures 111, of any desired shape and size, with any desired distance between the apertures and may place the apertures in any desired pattern. A triangle grid aperture pattern offers certain advantages discussed herein, but other aperture patterns may also be used, for example a quadrilateral grid pattern. FIG. 1 illustrates an equilateral triangle grid aperture pattern with a property that each aperture (except those at the border) is surrounded by six equidistant neighbors. FIG. 2 illustrates a quadrilateral grid aperture distribution. Other quadrilateral grid distributions may define rectangles or diamond shapes (not necessarily squares). Further aperture distribution types may include for example pentagonal, hexagonal, and other polygonal-based distributions.

In general the triangle-based aperture layout of FIG. 1 allows for more circuit design options than a quadrilateral layout such as FIG. 2. For example, on a triangle-based aperture layout, each non-polarized electronic component has three (3) orientations leading to different circuit design outcomes, and each polarized electronic component has six (6) orientations leading to different circuit design outcomes. On a quadrilateral aperture layout, non-polarized electronic components have only two (2) orientations leading to different circuit design outcomes, and polarized electronic components have four (4) orientations leading to different circuit design outcomes. Non-polarized components comprise, for example, resistors, non-polarized capacitors, coils. Polarized components comprise for example diodes, polarized capacitors, transistors and integrated circuits.

In some embodiments, a board may comprise a grid pattern which defines a plurality of circuit point positions. For example, a board may comprise a grid pattern which defines circuit point positions at the positions occupied by apertures on boards 112 or 113. Apertures may be included at a subset of the circuit point positions, and some embodiments may not include apertures.

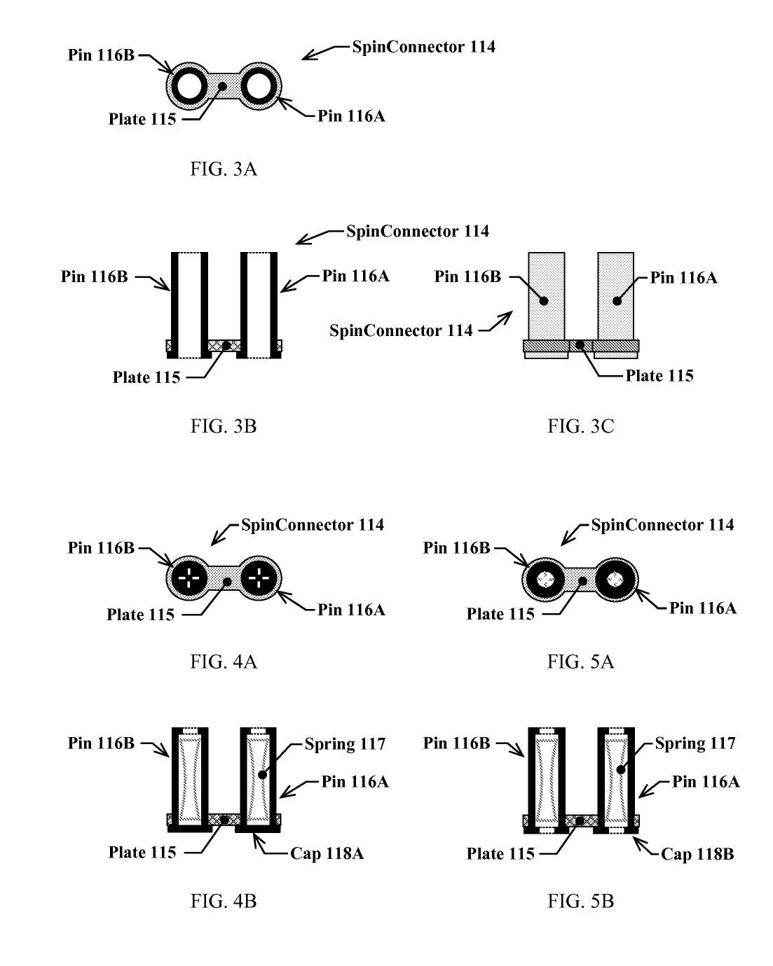

FIG. 3A is a diagram illustrating a top view of an example SpinConnector 114. The terms “connector” and “pin connector” are also used herein to refer to a SpinConnector. SpinConnector 114 includes a plate 115 and one or more pins 116A and 116B. Pins 116A and 116B and plate 115 may be made of conductive material. Conductive material may include, for example, electrically conductive material such as metal, optically conductive material such as optical fibers, glass or plastic, thermally conductive material such as metal, magnetically conductive material that is capable of sensing or emitting a magnetic field, acoustically conductive material that is capable of sensing or emitting sound vibrations, and/or wirelessly conductive material that it is capable of emitting or receiving an electromagnetic signal. The plate 115 comprises pin receptacles—which in the illustrated embodiment are circular holes in the plate 115 into which the pins 116A and 116B fit.

The pin receptacles may be adapted to make conductive contact with a sidewall of a pin insertable into the pin receptacles. The plate 115 further comprises a conductive bridge portion disposed between the pin receptacles. The bridge forms a conductive connection between pin receptacles. In some embodiments, the bridge portion may be insulated. In some embodiments, the bridge may allow conductive connections thereto, such as by soldering, conductive glue, crimping and so forth. In embodiments using a perforated board as shown in FIG. 1 and FIG. 2, the length of the distance between the pin receptacles may be equal to a multiple (1, 2, 3, etc.) of a distance between apertures of a corresponding perforated board, allowing pins to be inserted into both plate pin receptacles and perforated board apertures.

Pins 116A and 116B may be insertable into the pin receptacles on a plate, to form a conductive connection between a pin sidewall and the plate. Pins may comprise an interior cavity, a conductive pad allowing soldering or otherwise conductively affixing electronic component terminals to the pad, or a conductive jack for connection to one or more of an electronic component, a plate with receptacle, and a pin with cavity, as described in detail herein. While pins 116A and 116B are illustrated as cylindrical and the pin receptacles are illustrated as circular, other, non-circular embodiments are also possible. For example, oval shapes as well as square, hexagonal, octagonal, dodecagonal, and other polygonal shapes, may be used. Embodiments in which pins are in a same polygon or non-circular shape as pin receptacles allow a limited set of predefined positions to exist between pins and pin receptacles. Such arrangements offer the possible advantage of limiting the available orientations between pins 116 and plate 115. The available orientations may in some embodiments match angles between apertures of a perforated board as illustrated in FIG. 1 and FIG. 2.

The pins 116 may include any of a variety of pin features that are disclosed herein. Generally, pins 116 are adapted to be couplable with a terminal of an electronic component (not shown in FIG. 3A), and optionally also with one or more plates, to form at least a portion of a circuit. Pins 116 may be of uniform diameter in some embodiments, or may be of various diameters as desired for particular implementations. Corresponding pin receptacle and aperture diameters may also vary to accommodate pin diameter. Pin diameter may vary for example to accommodate terminals of different diameters and also to handle conductivity requirements for the pin. For example, high electrical current generally will require larger pin diameter and thicker pin sidewalls than low electrical current. Plate and electronic component terminal widths and thicknesses may also vary according to conductivity requirements.

The term “terminal” is used herein to refer to an element of an electronic component allowing for establishing a conductive connection with the component. Many electronic components have wires extending therefrom which are also referred to in the art as “leads”. Leads are one example of terminals. In some embodiments, a terminal may be securely held in conductive contact with the pin. The terminal may for example be soldered to the pin, crimped in place, glued using electrically conductive glue, inserted into a pin interior cavity, or some combination of these.

FIG. 3B is a diagram illustrating a cross section view of an example SpinConnector 114. SpinConnector 114 includes a plate 115 and pin 116A and 116B. In this embodiment, the pins 116A and 116B are cylindrical and the sidewalls of the pin cylinders are shown.

FIG. 3C is a diagram illustrating a side view of an example SpinConnector 114. SpinConnector 114 includes a plate 115 and pins 116A and 116B.

FIG. 4A-FIG. 4B are diagrams illustrating a SpinConnector 114 with a cap 118A and a spring contact element 117. Cap 118A serves to hold the spring 117 in place. Spring contact element 117 is inserted into pins 116A and 116B to improve conductive contact between the pins 116A and 116B and an inserted terminal of an electronic component. FIG. 4A illustrates a top view of plate 115 and pins 116A and 116B, showing darkened interior pin cavity indicating an inserted spring contact element. FIG. 4B illustrates a cross section view of the SpinConnector 114, including plate 115 and pins 116A and 116B. Example pin 116A includes spring 117 and cap 118A.

The spring 117 is one example of a contact element that may be inserted into an interior cavity inside a pin. A contact element may be used to improve conductive contact between the pin and an electronic component terminal. A contact element may also serve to more securely hold the terminal physically in place. The illustrated spring is discussed in greater detail below.

FIG. 5A-FIG. 5B are diagrams illustrating a SpinConnector 114 with a cap 118B and a spring contact element 117. Cap 118B serves to hold the spring 117 in place, and includes a cap hole allowing insertion of an electronic component terminal from either end of the pins 116A and 116B. FIG. 5A illustrates a top view of plate 115 and pins 116A and 116B, showing darkened interior pin cavity indicating an inserted spring contact element. FIG. 5B illustrates a cross section view of the SpinConnector 114; including plate 115 and pins 116A and 116B. Example pin 116A includes spring 117 and cap 118B.

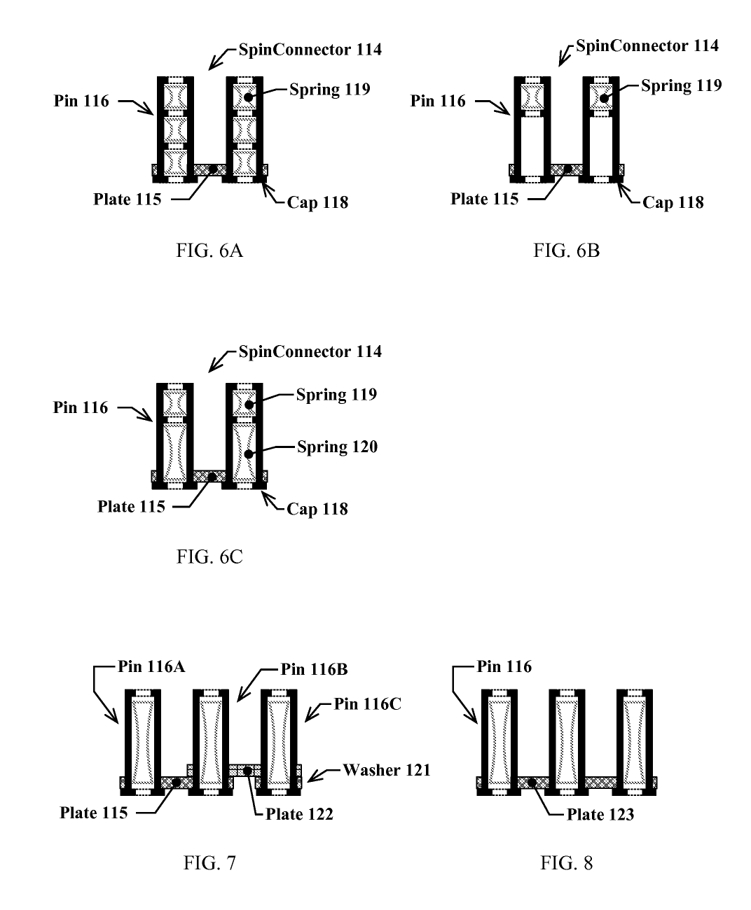

FIG. 6A is a diagram illustrating an example SpinConnector 114 with multiple spring contact elements 119, as well as plate 115, pin 116 and cap 118. This arrangement may improve electrical, thermal, and/or mechanical contact in some embodiments. Pin sidewalls may include contact element supports, as shown.

FIG. 6B-FIG. 6C are variants of FIG. 6A designed for short or long terminals. FIG. 6B shows use of a single small spring contact element 119 adapted to receive a short terminal, as well as plate 115, pin 116 and cap 118, while FIG. 6C shows use of a small spring contact element 119 adapted to receive a short terminal and a mid-size spring contact element 120 adapted to receive a longer terminal, as well as plate 115, pin 116 and cap 118.

FIG. 7 is a diagram illustrating a chain of SpinConnectors, created by inserting a pin through a pin receptacle on two or more plates. Pin 116A is inserted in plate 115. Pin 116B is inserted in plates 115 and 122. Plates 115 and 122 may thus be in conductive contact with one another. Plates 115 and 122 may also articulate around pin 116B in some embodiments, or may be in a fixed orientation by for example soldering, gluing, or crimping the plates in place. Pin 116B may therefore serve as a joint in the illustrated SpinConnector. In embodiments allowing articulation, cylindrical pin shapes allow for smooth and continuous movement while oval/polygonal shapes restrict allowable pin/plate orientations. Pin 116C may optionally be inserted into a washer 121 as well as plate 122 to place pin 116C at a same level as pins 116A and 116B.

The term “circuit point” is used herein to refer to a location at which an electronic component terminal is in conductive contact with a pin or plate. Thus, any of the pins 116A, 116B and 116C in FIG. 7, as well as the various other pin, receptacle, conductive pad, jack and other structures provided herein, may serve as a circuit point. In some embodiments, pin-less circuit points may be utilized, in which an electronic component is in conductive contact with a plate, at a location without a pin. For example, an electronic component terminal may be soldered or otherwise affixed directly to a plate. Some plates may comprise terminal receptacles, illustrated in FIG. 48, in which an electronic component terminal is inserted, rather than a pin. A receptacle may be characterized as a terminal receptacle or a pin receptacle based on whether a terminal or pin is inserted. Receptacles may be of any diameter as necessary to accommodate corresponding pins and/or terminals. In some embodiments, some plates may comprise conductive jacks as circuit points. Conductive jacks may be designed to fit as a male structure into a corresponding female structure disposed on one or more of an electronic component, a plate with receptacle, and a pin with cavity, as illustrated in FIG. 49. In some embodiments, jacks may be designed as a female structure, to receive a counterpart structure. For example, a female jack structure may comprise a cavity adapted for an audio, data, video, optical or other cable or plug structure, which may conform to any of the standard interface specifications.

FIG. 8 is a diagram illustrating use of a plate 123 including three pin receptacles. Example pins 116 are disposed in the pin receptacles. It will be appreciated that a wide variety of plate/pin receptacle combinations are possible, several of which are illustrated further below.

The technique for combining SpinConnectors illustrated in FIG. 7, along with the option of alternative plate configurations as illustrated in FIG. 8 allow for configuring printed circuit board-like circuits in some embodiments, with the pin and plate connector structures forming the traces and vias of the circuit.

It should be noted that the SpinConnector structures disclosed in FIG. 3-FIG. 8 can be used with or without a corresponding perforated board. The use of a perforated board is discussed in connection with a variety of the figures below. In embodiments not making use of a perforated board, oval/polygonal pin receptacles and pin shapes may have additional advantages in restricting connection angles to promote organized circuit design. Also, without presence of a perforated board the SpinConnector structures can be smaller and shorter in height which may be advantageous in certain applications.

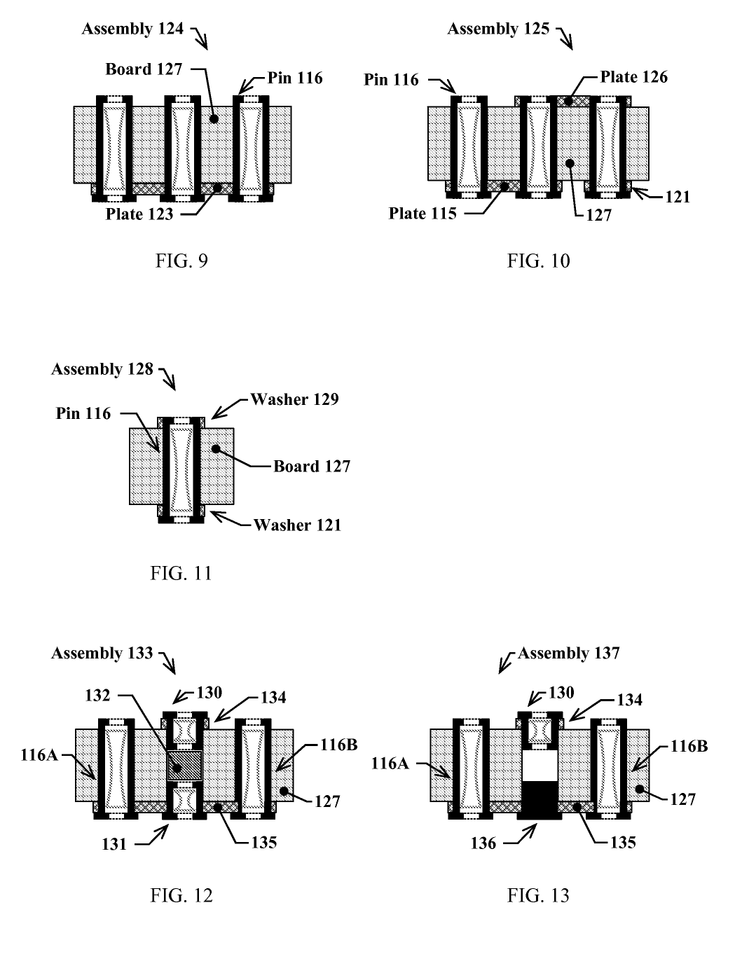

FIG. 9 is a diagram illustrating an example assembly 124 including perforated board 127, pins 116 and plate 123. The pins 116 are inserted through apertures in the board 127. The apertures may be of similar diameter as pins 116 so that the pins fit snugly in the board 127. The pins 116 may pass through the entire board 127 optionally leaving room for plate 123, and optionally extending some distance beyond the surface of the board 127, as shown. Electronic component terminals may connect to either end of pins 116 by soldering, crimping, or insertion into the pin internal cavity, or some combination of these as discussed above. FIG. 9 shows the plate 123 disposed on just one side of the board 127, with pins 116 that allow for terminal connections on either end.

FIG. 10 is a diagram illustrating an example assembly 125 similar to that of FIG. 9, including pins 116 and a board 127. In FIG. 10, plate 115 is disposed on one side of the board while plate 126 is disposed on the opposite side. A washer 121 maintains the rightmost pin at a same level as the other pins. Electronic component terminals may connect to either end of pins 116 by soldering, crimping, or insertion into the pin internal cavity, or some combination of these as discussed above. Plate 126 may be in conductive contact with the illustrated pins using any of a variety of contact methods, including for example soldering, crimping, conductive glue and the like.

FIG. 11 is a diagram illustrating an example assembly 128 including a board 127 with a single-pin SpinConnector inserted into an aperture. The single pin connector includes pin 116 which may optionally be fitted with a cap and contact element as shown, and washer 121 which does not bridge to another pin. Washer 129 may also be in contact with pin 116 in some embodiments, also without creating an electrical connection to another pin. In some embodiments, the single pin connector can serve to connect electronic components on opposite sides of the board 127. It may also be used to house terminals that do not connect to an electrical circuit.

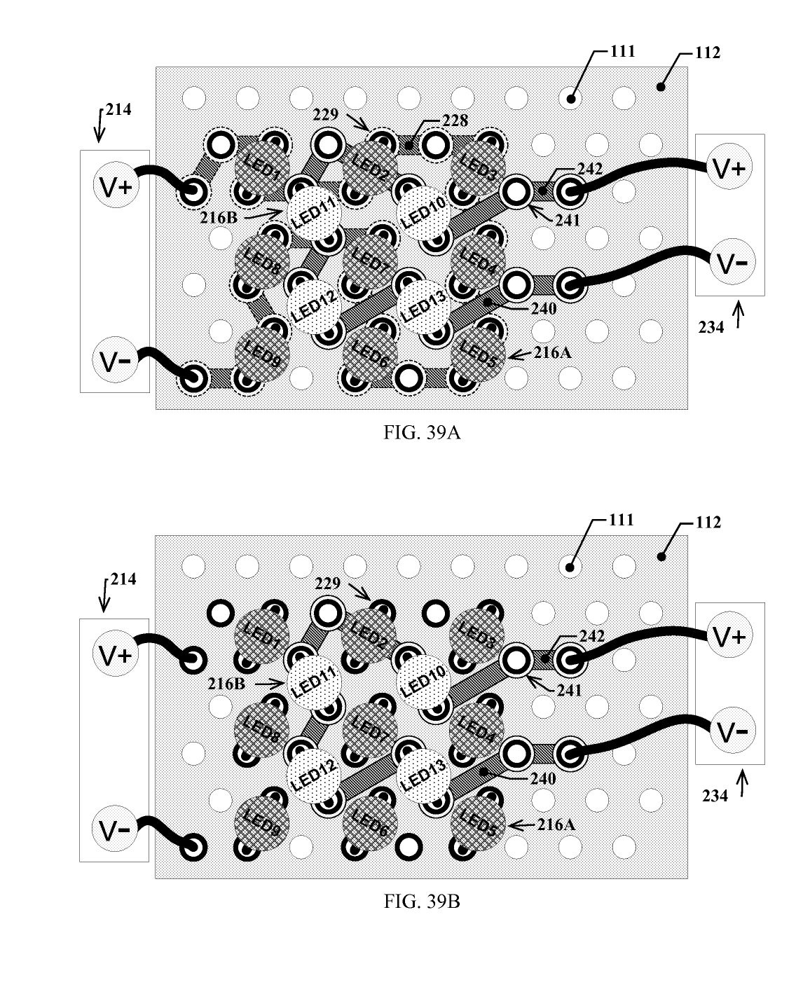

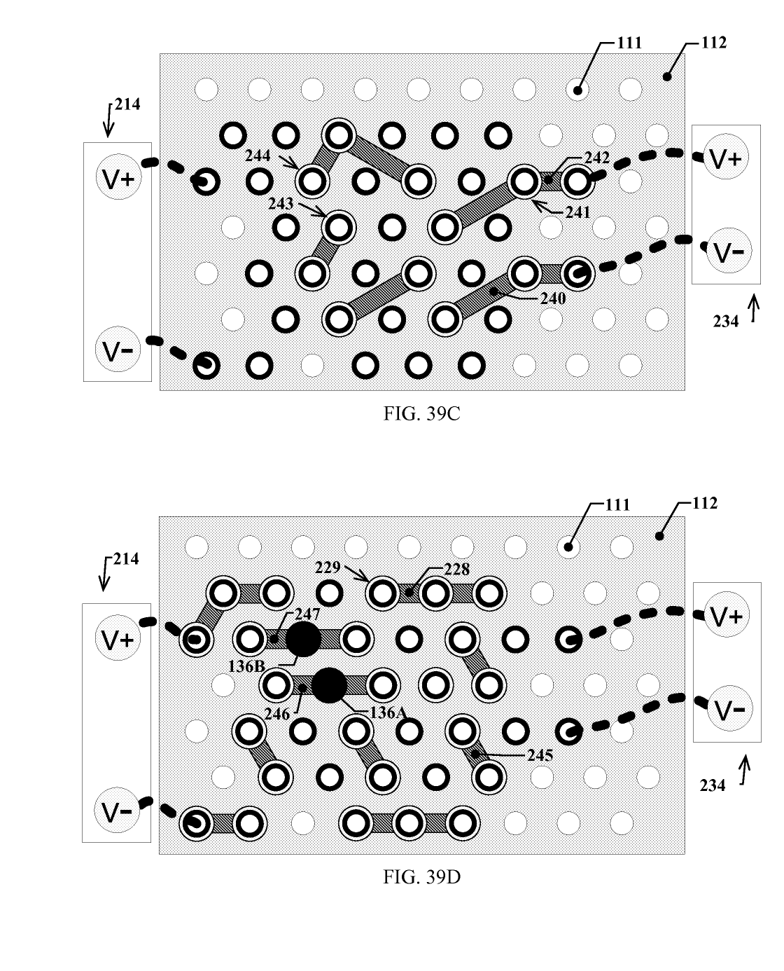

FIG. 12 is a diagram illustrating an example assembly 133 including a board 127 with overlapping SpinConnector structures. A first SpinConnector includes pin 116A, short pin 131, plate 135, and pin 116B. A second SpinConnector includes short pin 130 and plate 134. Plate 134 connects short pin 130 and pins that are not in the cross sectional view. Refer to FIG. 39C and FIG. 39D for top and bottom views of a similar structure to that shown in FIG. 12. FIG. 12 also illustrates a spacer 132 disposed in a gap between short pin 131 and short pin 130.

The assembly 133 allows overlapping traces by preventing conductive contact between the first and second SpinConnector structures. Spacer 132 is optionally used as a safety device to prevent accidental conductive contact, for example between a short pin and a long pin inadvertently inserted into the same aperture. Other circuit overlap methods may also be used as discussed herein.

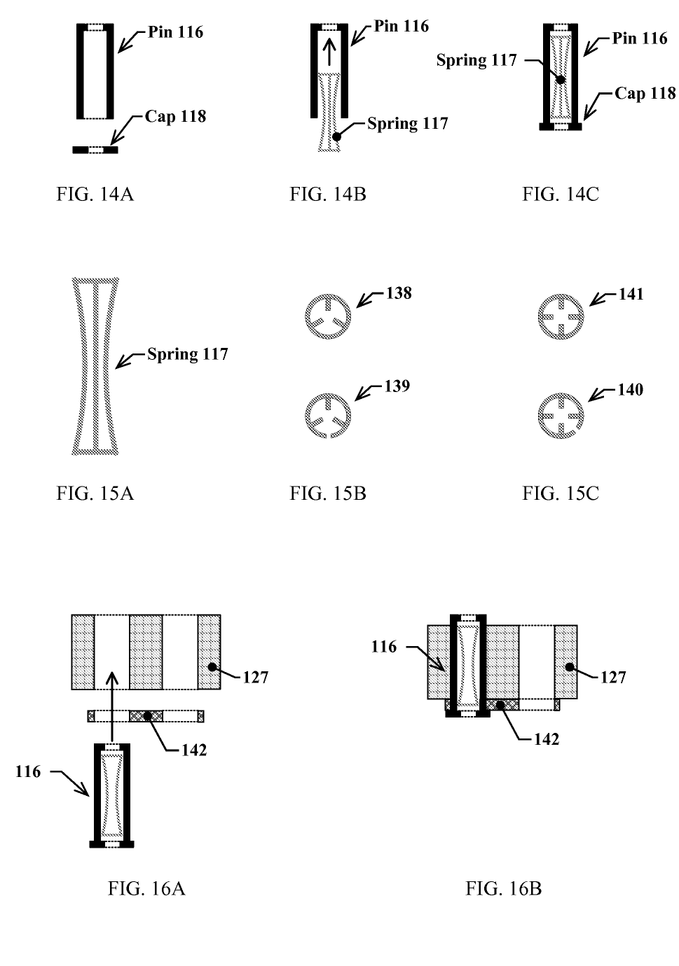

FIG. 13 is a diagram illustrating an example assembly 137 including a board 127 with overlapping SpinConnector structures. A first SpinConnector includes pin 116A, plug 136, plate 135, and pin 116B. A second SpinConnector includes short pin 130 and plate 134. As in FIG. 12, plate 134 connects short pin 130 and pins that are not in the cross sectional view. Here, plate 135 is in conductive contact with both pin 116A and pin 116B, and provides a connection between these pins which bypasses the aperture into which plug 136 is inserted. Here, plug 136 ensures that only a short pin such as 130 can be inserted from the other side of the board 127, to prevent a short-circuit (“shorting”) between the first and second SpinConnectors.

FIG. 14A-FIG. 14C are diagrams illustrating example manufacture of a pin. FIG. 14A shows cross section view of a pin 116 and a cap 118. Pin 116 includes a rim at the top which may be included to hold a contact element in place. FIG. 14B shows a pin 116 being fitted with a spring contact element 117. FIG. 14C shows manufactured pin 116 with spring 117 and cap 118 in place. Cap 118 may be held in place while maintaining a conductive connection between the cap and pin sidewall, for example by soldering or gluing the cap to the pin sidewalls using conductive glue.

FIG. 15A-FIG. 15C show close up views of a spring contact element 117. FIG. 15A provides a side view. FIG. 15B provides top/bottom view 138 and top/bottom view 139. Top/bottom view 138 includes a rigid perimeter while top/bottom view 139 includes an opening in the perimeter to allow squeezing the spring to a smaller diameter to allow for insertion into a pin. Embodiments configured according to top/bottom view 139 may allow for insertion of the spring with cap and rim in place, for example to produce structures as illustrated in FIG. 6A-FIG. 6C. FIG. 15C provides top/bottom view 141 and top/bottom view 140. These are analogous to top/bottom view 138 and top/bottom view 139, with four longitudinal members instead of three to emphasize that numerous alternative configurations are feasible.

FIG. 16A illustrates a pin 116, plate 142, and perforated board 127 comprising two apertures. The pin 116 may be inserted through a pin receptacle in plate 142, and also through an aperture in board 127 as shown in FIG. 16A to produce the result illustrated in FIG. 16B. Any of the various pin and plate structures disclosed herein may be assembled as illustrated in FIG. 16. Using the illustrated assembly technique, circuit traces may be easily positioned and oriented, and repositioned and reoriented to build custom, reconfigurable circuit designs. In the illustrated embodiment, the apertures of the perforated board 127 are not activated to allow conductive connections with electronic components until the designer places the pin 116.

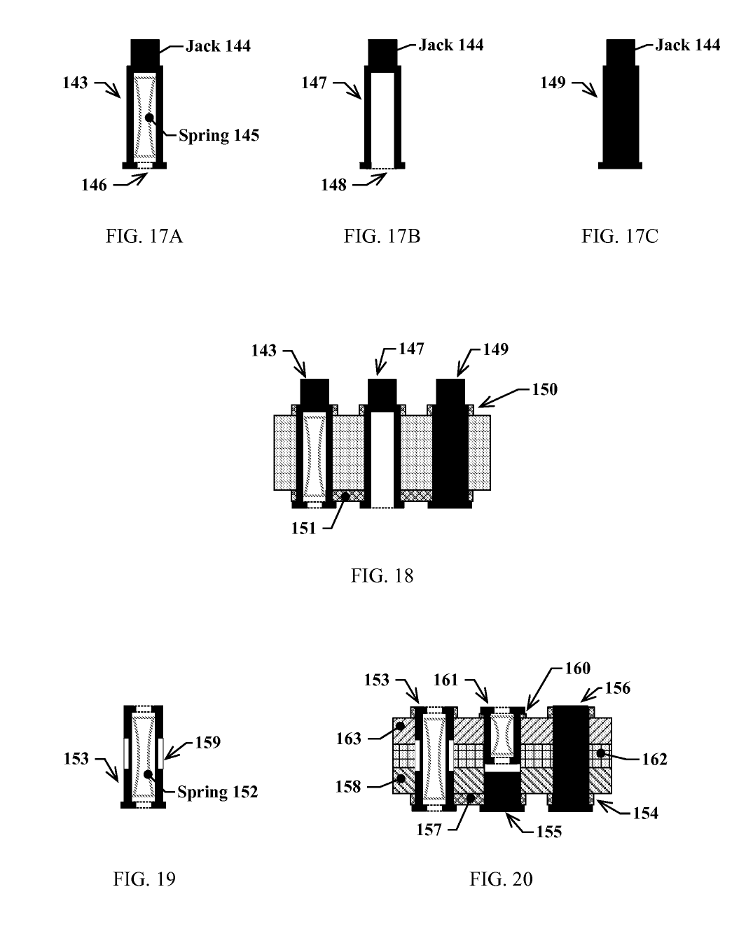

FIG. 17 illustrates various pins fitted with a jack 144 designed to fit as a male structure into a corresponding female structure disposed on one or more of an electronic component, a plate with receptacle, and a pin with cavity. As described above, in some embodiments, jacks may also be designed as a female structure, comprising a cavity adapted for an audio, data, video, optical or other cable or plug structure, which may conform to any of the standard interface specifications. The use of a jack 144 is one alternative for establishing contact between pins and electronic components. Other alternatives include the use of pin interior cavities and solder pads. FIG. 17A illustrates a pin 143 with interior cavity fitted with spring 145, and a cap 146 with hole for receiving an electronic component terminal. FIG. 17B illustrates a pin 147 with large cap opening 148, into which a jack such as 144 or similar structure (as may be disposed on an electronic component) may be inserted. An electronic component terminal may otherwise be brought into conductive contact with pin 147 by inserting the terminal into opening 148 and optionally soldering, gluing, or otherwise affixing the terminal to a pin sidewall. FIG. 17C illustrates a pin 149 with no internal cavity, where the cap side opposite the jack 144 may serve as a solder pad.

FIG. 18 illustrates a SpinBoard assembly in which pins 143, 147, and 149 are inserted into plate 151 to form a SpinConnector structure. The jacks of the pins 143, 147, and 149 may plug into one or more of electronic components, plates with receptacles, and pins with cavities. Washers such as 150 may optionally be used to stabilize the pins, by for example holding the pins in place so they do not slide out of the apertures. Other techniques for preventing slippage of the pins include tight friction fit, barb-type structures that allow pin insertion but prevent pin removal, and inserting plug structures into pins such as 147 to expand the circumference of the pin once inserted into an aperture, to provide increased friction between the outside of the pin sidewall and the aperture.

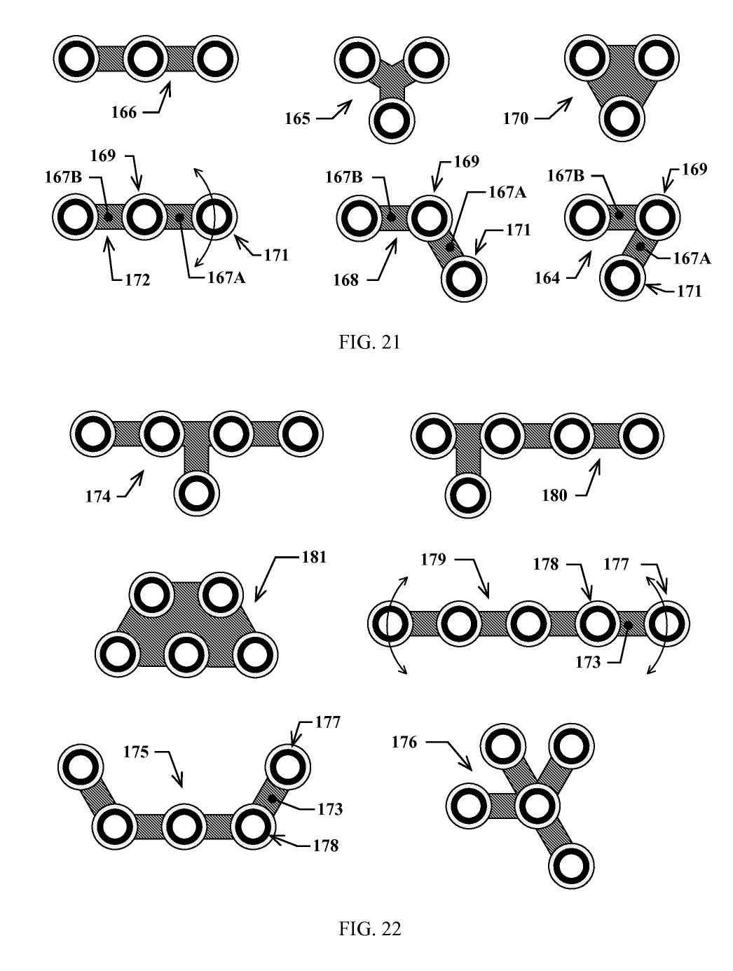

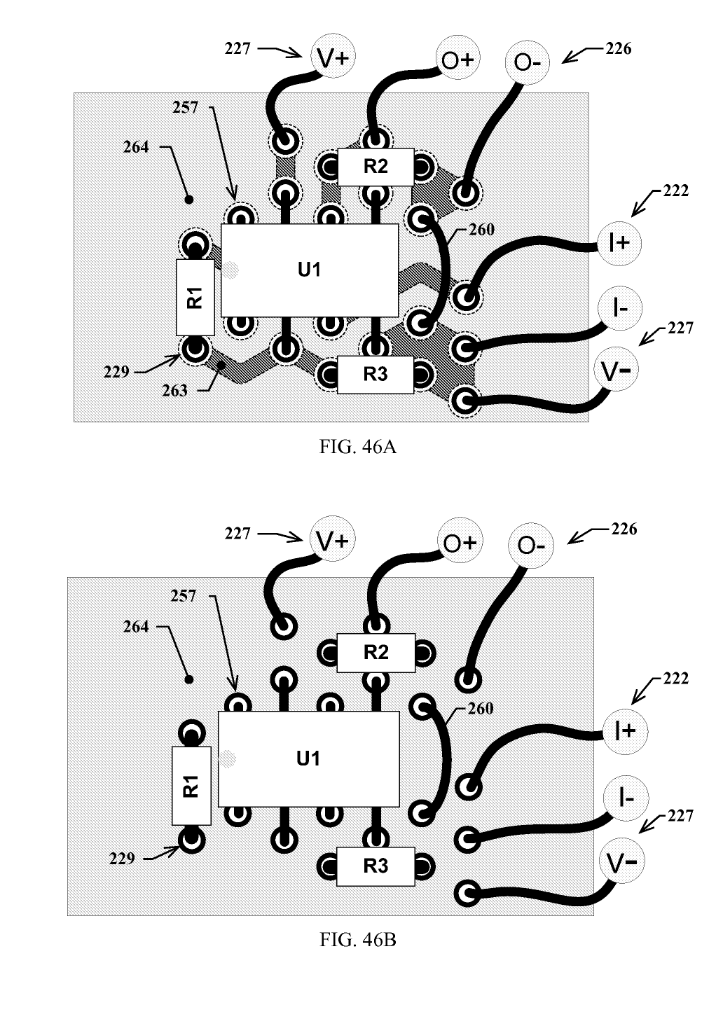

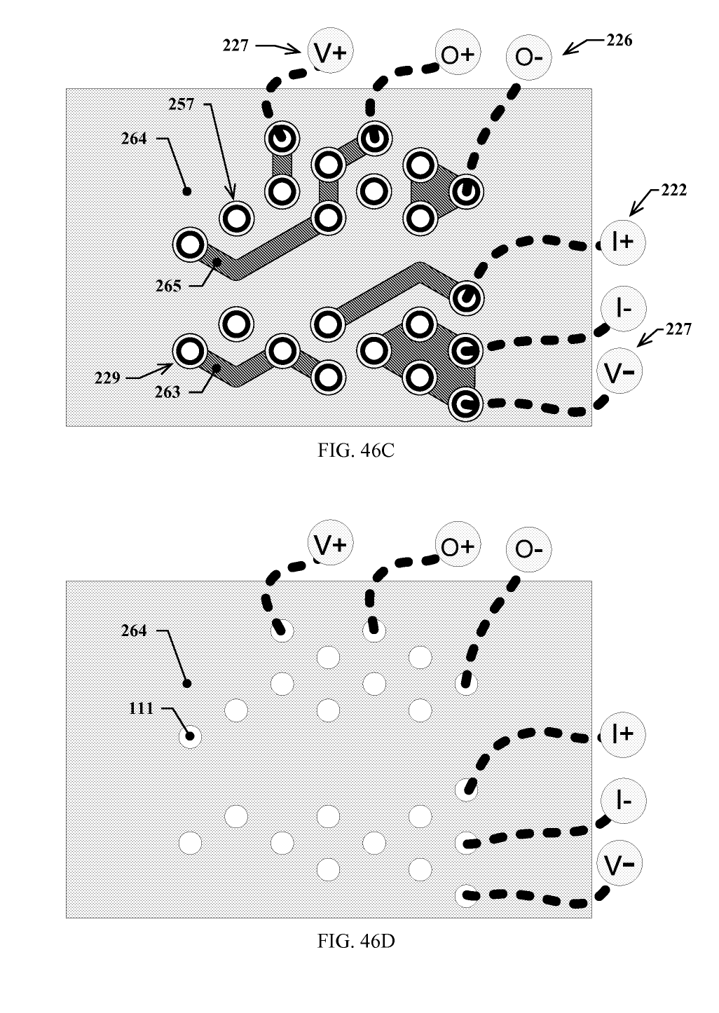

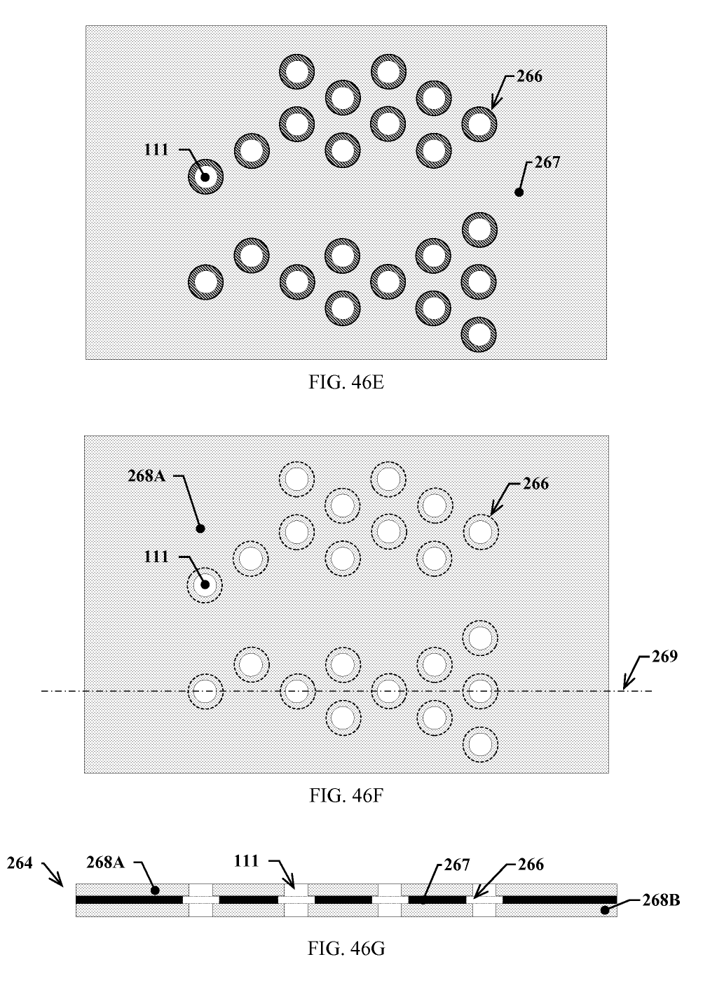

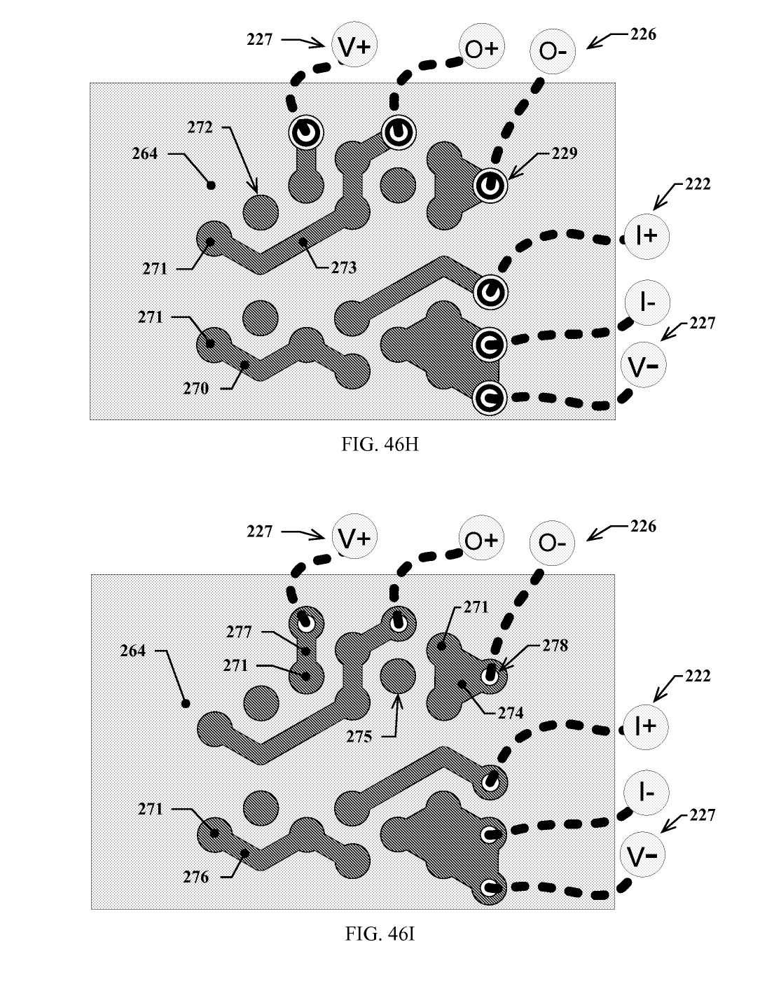

FIG. 19-FIG. 20 illustrate example pins adapted for multilayer SpinBoard embodiments, such as illustrated in FIG. 46G. FIG. 19 illustrates a pin 153 with an isolation boundary 159 located on the pin 153 to isolate the pin 153 from one or more layers of a layered perforated board. FIG. 20 illustrates a SpinBoard assembly comprising a perforated board including multiple layers. The layers compromise layer 163, layer 162 and layer 158. Inserted in the perforated board are pins 153, 161, 155, and 156. Pin 153 is illustrated in FIG. 19. FIG. 20 illustrates that pin 153 may be isolated from a layer such as layer 162. Pin 161 illustrates an intermediate length pin designed to make conductive contact with a middle layer 162 of a multilayer perforated board. Pin 155 illustrates a short pin without internal cavity, and short enough to avoid conductive contact with middle layer 162 and pin 161. Pin 155 may be in conductive contact with an electronic component for example by soldering a component terminal to the pin cap. Pin 156 illustrates an example pin that is designed for conductive contact along its entire length, and is capable of conductive contact with electronic components on both sides of the perforated board as well as with middle layers of the perforated board.

In FIG. 20, elements 154 and 160 may comprise washers or plates oriented non-parallel to the cross section plane. Plate 160 is a thin plate which may serve to position pins at a same height or to appropriately separate pins 161 and 155. Pin 161 may serve the function of providing a connection to a middle layer 162, for example a ground plane, and is useful for this purpose in both single pin and multi-pin SpinConnector embodiments. Pins 153 and 155 are connected by plate 157 to form a SpinConnector that is not in conductive contact with middle layer 162, in the illustrated embodiment.

FIG. 21-FIG. 23 illustrate example SpinConnector structures. In general, a wide variety of SpinConnector configurations are possible, and some examples are provided herein. SpinConnectors can include any number of pin receptacles and can comprise single fixed plates in a wide variety of shapes and sizes and can also include articulating plates allowing for angle adjustment. Articulating plates may be formed by joining plates at a pin receptacle with a pin. SpinConnectors may include a pin receptacle for every aperture over which the SpinConnector will span, as illustrated for the connectors in FIG. 21-FIG. 23, or SpinConnectors may be designed to span over one or more apertures on a perforated board without a corresponding pin receptacle. Combinations of SpinConnectors illustrated in FIG. 21-FIG. 23 allow for configuring printed circuit board-like circuits in some embodiments, with the pin and plate connector structures forming the traces and vias of the circuit.

FIG. 21 illustrates example SpinConnectors with three (3) pin receptacles. SpinConnector 166 includes a single plate with three (3) pin receptacles in a straight line. SpinConnectors 165 and 170 include single plates with three (3) pin receptacles in a triangle configuration. SpinConnector 165 is in a branching configuration, while SpinConnector 170 is in a cluster configuration. SpinConnectors 165 and 170 may be selected for conductive properties. For example, electrical current flow will be different for a structure such as 165 as it would be for 170. Thermal behavior will also vary.

SpinConnector 172 may comprise two plates 167A and 167B, joined by a pin inserted into a pin receptacle 169 to allow for articulation. For example, SpinConnector 172 can articulate to produce structures such as 168 and 164, by rotating plate 167A around pin receptacle 169. Structures such as 168 and 164 may be made using an articulating connector, or may be configured as single-plate non-articulating structures with an angular bend in the plate.

FIG. 22 illustrates example SpinConnectors with five (5) pin receptacles. All of the examples in FIG. 22 may be formed of a single-plate or of multiple, articulating plates, with the exception of SpinConnector 181. SpinConnectors 174, 180, and 176 show different example branching patterns. SpinConnector 181 shows an example cluster pattern. SpinConnector 179 illustrates a linear arrangement which can be articulated into many configurations, including 175. When SpinConnector 179 is formed of chain of multiple articulating plates including plate 173, it can be configured to the shape of SpinConnector 175 by articulating plate 173 around pin receptacle 178, and similarly rotating the plate on the opposite end.

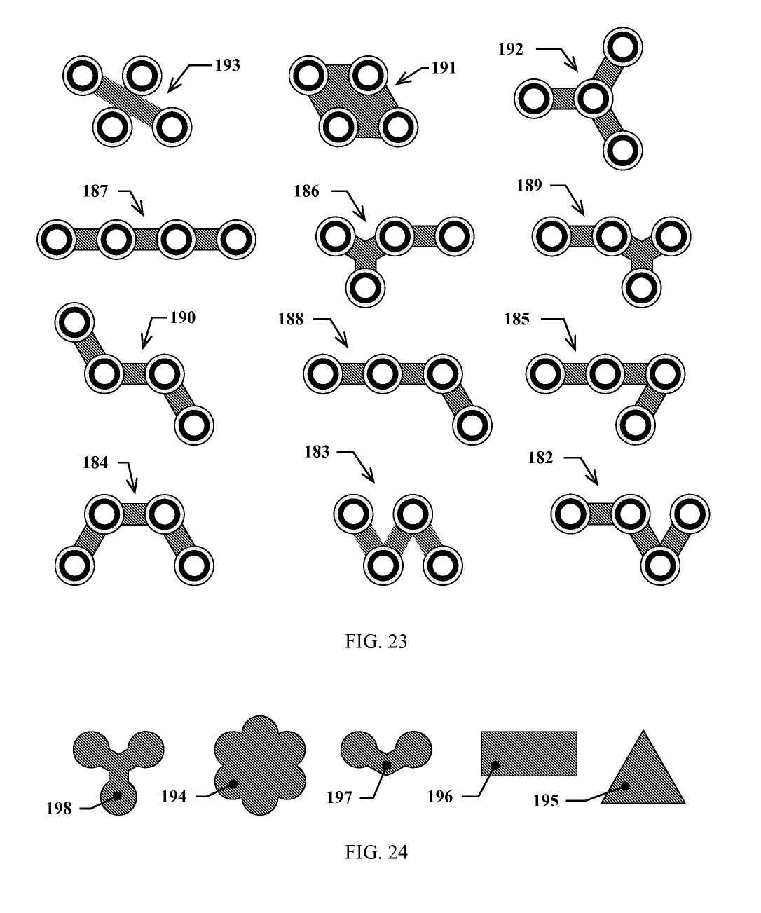

FIG. 23 illustrates example SpinConnectors with four (4) pin receptacles. All of the examples in FIG. 23 may be formed of a single-plate or of multiple, articulating plates, with the exception of SpinConnectors 193 and 191. SpinConnectors 193 and 191 demonstrate a same pin receptacle pattern with different plate structures which may be selected for desired electrical and thermal properties. SpinConnectors 193, 192, 186, and 189 show different example branching patterns. SpinConnector 191 shows an example cluster pattern. SpinConnectors 187, 190, 188, 185, 184, 183 and 182 illustrate a linear arrangement which can be articulated into many configurations, when formed of linked chains of appropriately articulating plates.

In conclusion, a wide variety of SpinConnector structures can be produced according to the teachings herein. SpinConnectors may provide for conductive connections between pins, and may furthermore support conductive connections directly with plates in some embodiments. The SpinConnector structures can include any number of pin receptacles, fixed plate structures of a variety of shapes and articulating plate structures which may also take any shape. SpinConnector structures may comprise branching, clustered, and chain structures (in linear, articulating, or angular formation) as desired.

FIG. 24 illustrates top views of a variety of expanded cap type pins as may be included in some embodiments. The illustrated expanded cap type pins 195, 196, 197, 194, and 198 include conductive pads as shown in FIG. 24, which spread beyond the diameter defined by pin sidewalls (pin sidewalls are not visible in FIG. 24). Expanded cap type pins may be used along with plates to form SpinConnectors with any of the properties discussed herein. The various illustrated pins may be brought into conductive contact with one another via plates or electronic components. Expanded cap type pins may expand in several directions as shown, while numerous other shapes and expansion patterns are possible.

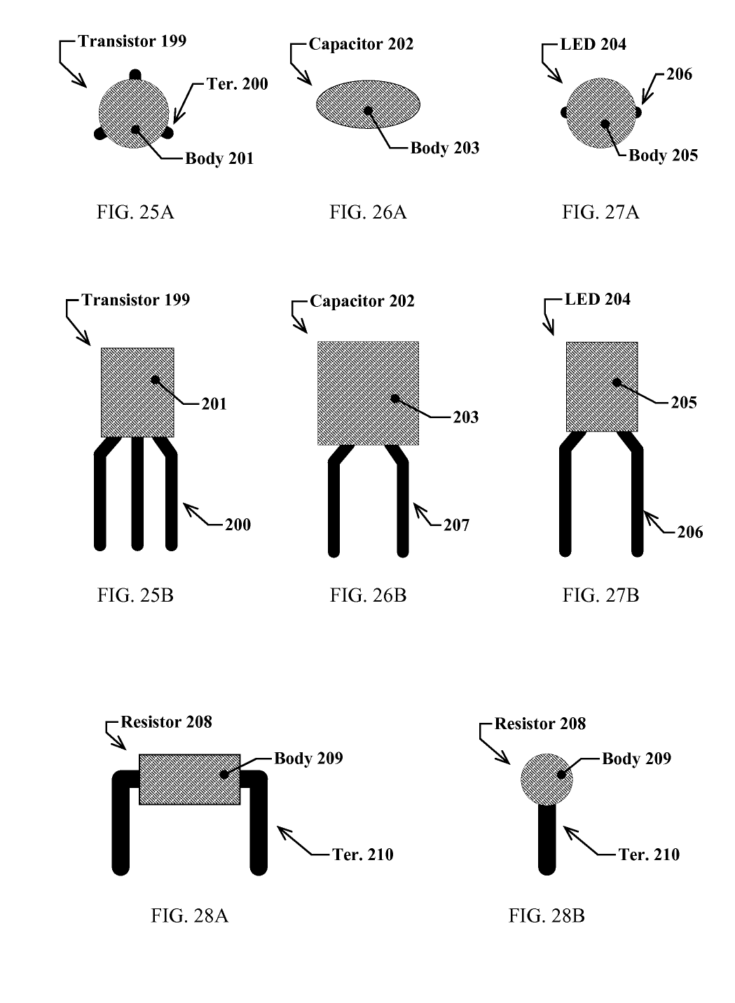

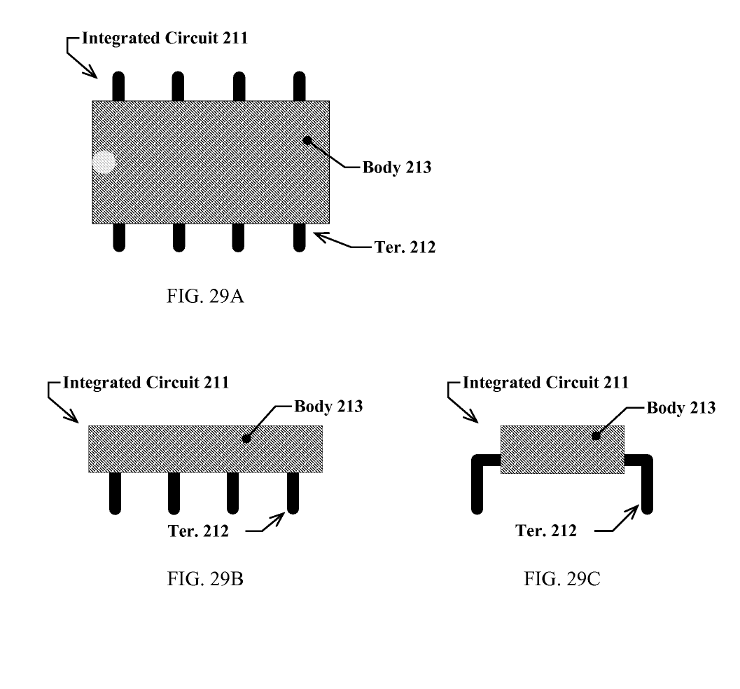

FIG. 25-FIG. 29 illustrate example electronic components with terminals that may be brought into conductive contact with pins. FIG. 25A is a top view of a transistor 199, showing transistor body 201 and terminals such as 200. FIG. 25B is a side view of a transistor 199, showing transistor body 201 and terminals such as 200. FIG. 26A is a top view of a capacitor 202, showing capacitor body 203. FIG. 26B is a side view of a capacitor 202, showing capacitor body 203 and terminals such as 207. FIG. 27A is a top view of a LED 204, showing LED body 205 and terminals such as 206. FIG. 27B is a side view of a LED 204, showing LED body 205 and terminals such as 206. FIG. 28A is a side view of a resistor 208, showing resistor body 209 and terminals such as 210. FIG. 28B is a front view of a resistor 208, showing resistor body 209 and terminals such as 210. FIG. 29A is a top view of an integrated circuit 211, showing integrated circuit body 213 and terminals such as 212. FIG. 29B is a side view of an integrated circuit 211, showing integrated circuit body 213 and terminals such as 212. FIG. 29C is a front view of an integrated circuit 211, showing integrated circuit body 213 and terminals such as 212.

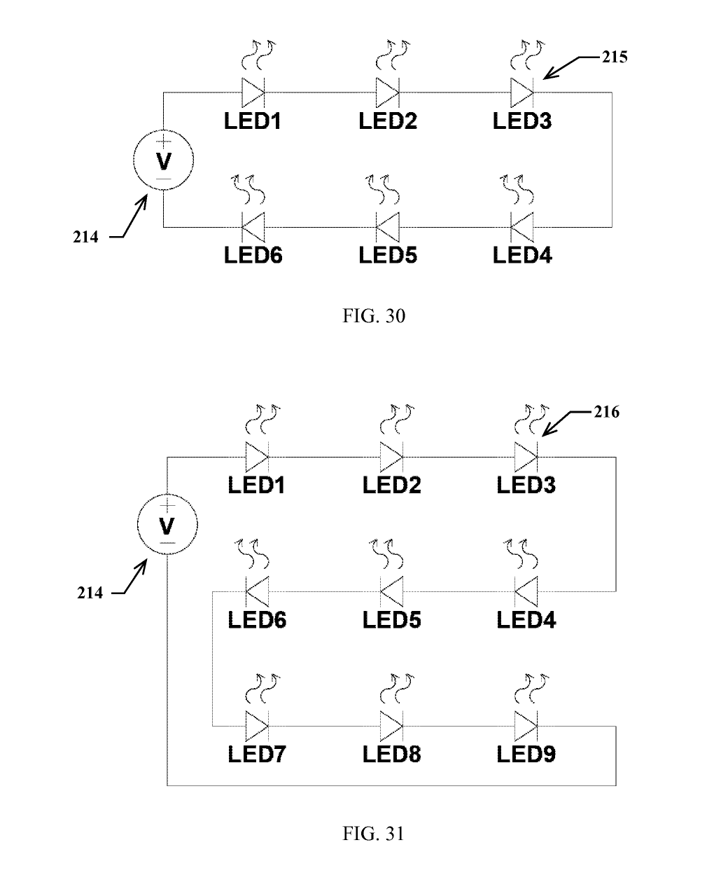

FIG. 30-FIG. 33 illustrate example circuits which are referenced in several of the remaining figures. FIG. 30 illustrates six electronic components, illustrated as LEDs such as example LEDs 215 and 216, in series on an electrical circuit connected to a power supply 214. FIG. 31 illustrates nine electronic components, illustrated as LEDs such as example LED 216, in series on an electrical circuit connected to a power supply 214.

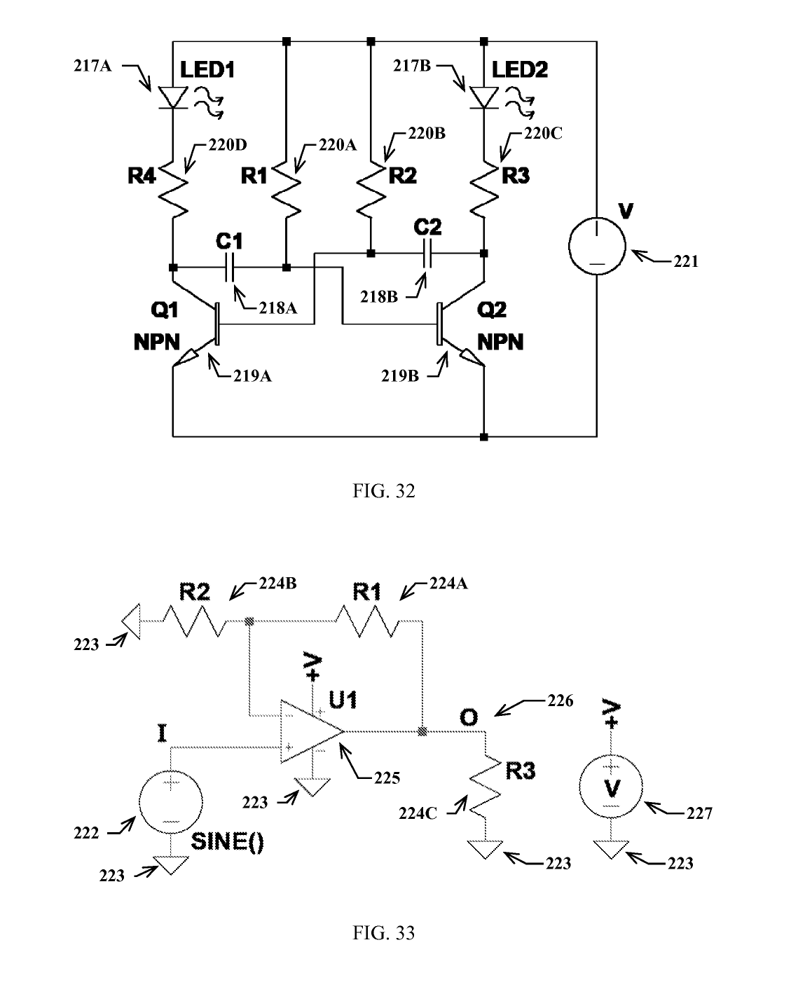

In FIG. 32, a power supply 221 (which may be coupled with a voltage regulator in some embodiments) is coupled to a circuit comprising LED1 217A and LED2 217B, resistors R1-R4 labeled as 220A, 220B, 220C, and 220D, capacitors C1-C2 labeled as 218A and 218B, and transistors Q1-Q2 of type NPN (typically comprising a layer of P doped semiconductor between two N-doped layers) labeled as 219A and 219B.

The circuit schema from FIG. 32 is an example of a more complex circuit than those illustrated in FIG. 30-FIG. 31, which is also accommodated by the illustrated SpinBoard design. The circuit of FIG. 32 is furthermore configurable and customizable for example by using different capacitors and resistors to change the flash rate, using different transistors and resistors to adjust current through the LEDs and thus LED intensity, applying a desired input voltage using a voltage regulator to adjust LED intensity and/or flash rate, and so forth. Either or both of LED1 217A or LED2 217B may furthermore be replaced by a chain of LEDs such as the LEDs connected in series as illustrated in FIG. 30-FIG. 31. It will be appreciated that elements such as an adjustable power supply, voltage regulator, current regulator, and a timer may be coupled to circuits disclosed herein to provide additional levels of control as desired.

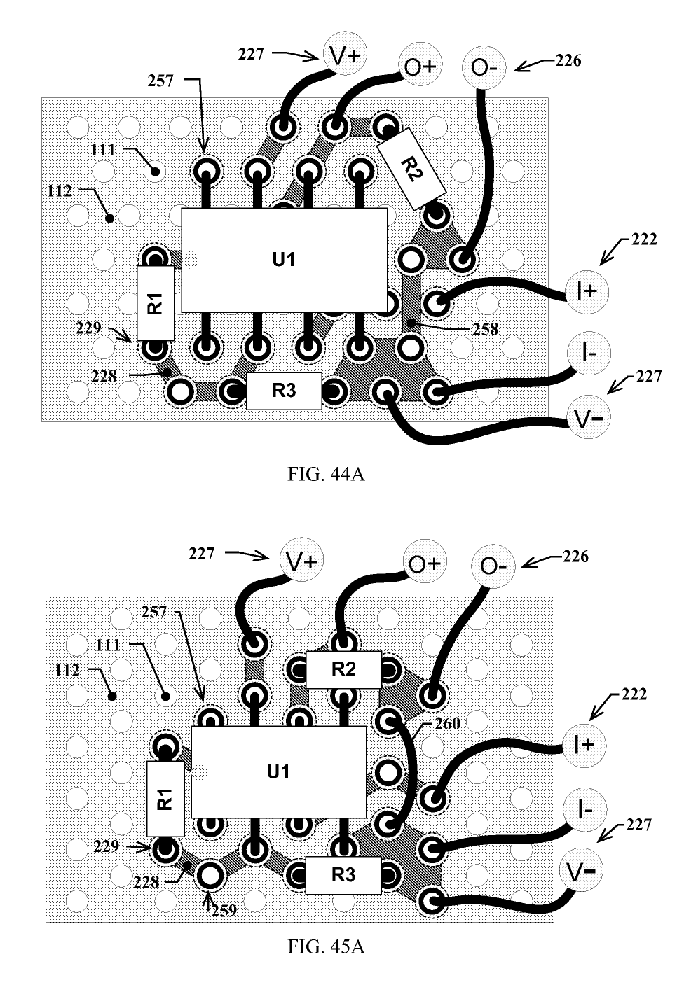

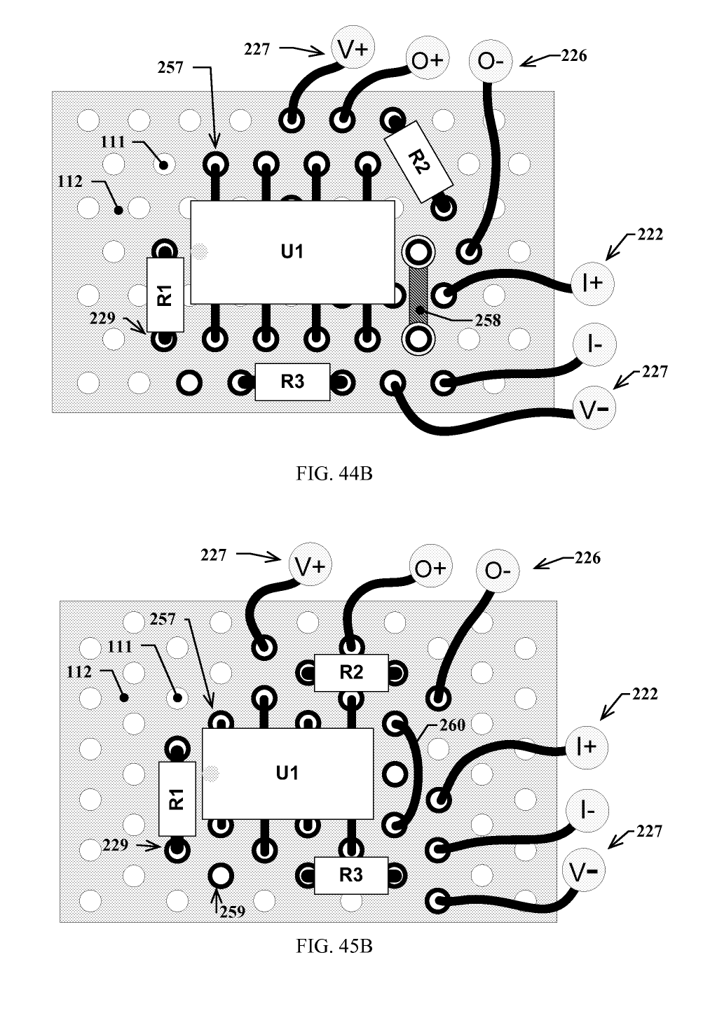

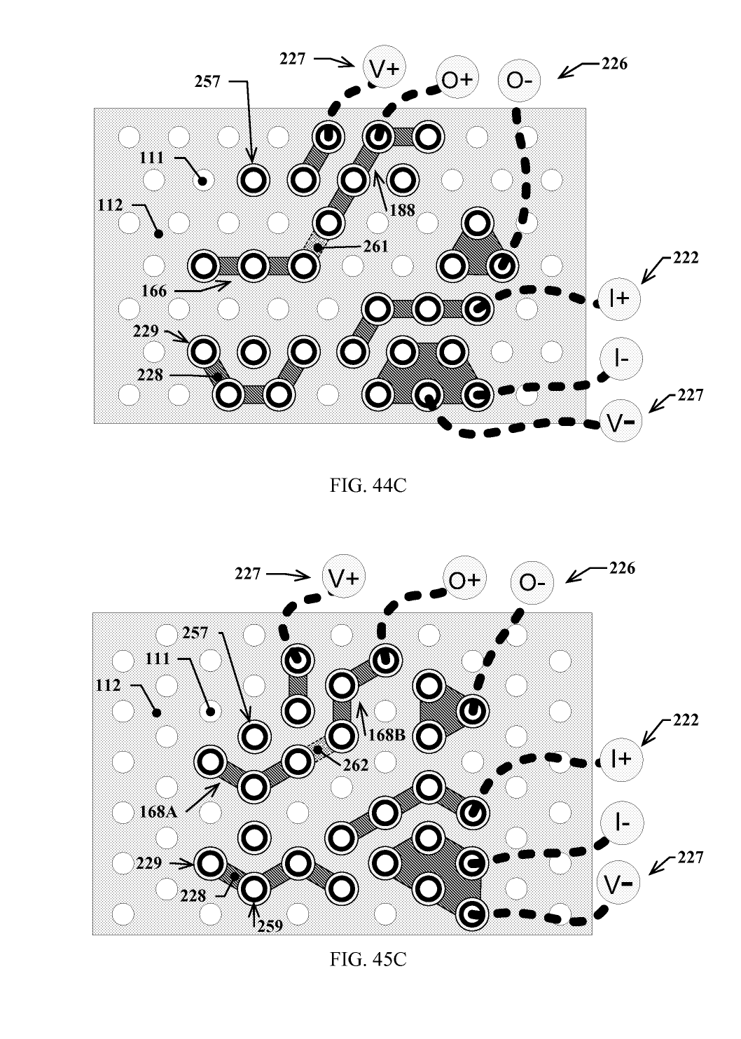

FIG. 33 provides an example circuit schema for a simplified amplifier circuit which is referenced in FIG. 44-FIG. 46. The simplified amplifier as well as more complex schemas may be accommodated by the illustrated assemblies set forth herein. A power supply 227 (which may be coupled with a voltage regulator in some embodiments) is coupled to a circuit comprising amplifier U1 225 and resistors R1-R3 labeled as 224A, 224B, and 224C. The power supply 227 is coupled to amplifier U1 225 at the connection labeled V+. Triangles 223 indicate a connection to ground.

In FIG. 33 an input signal (I) 222 is connected to the non-inverting input of the amplifier. An output signal (O) 226 is retrieved at the output of the amplifier. The input sine signal (I) may be amplified a predefined amount (the gain of the amplifier) which depends in part of the ratio of R1 and R2.

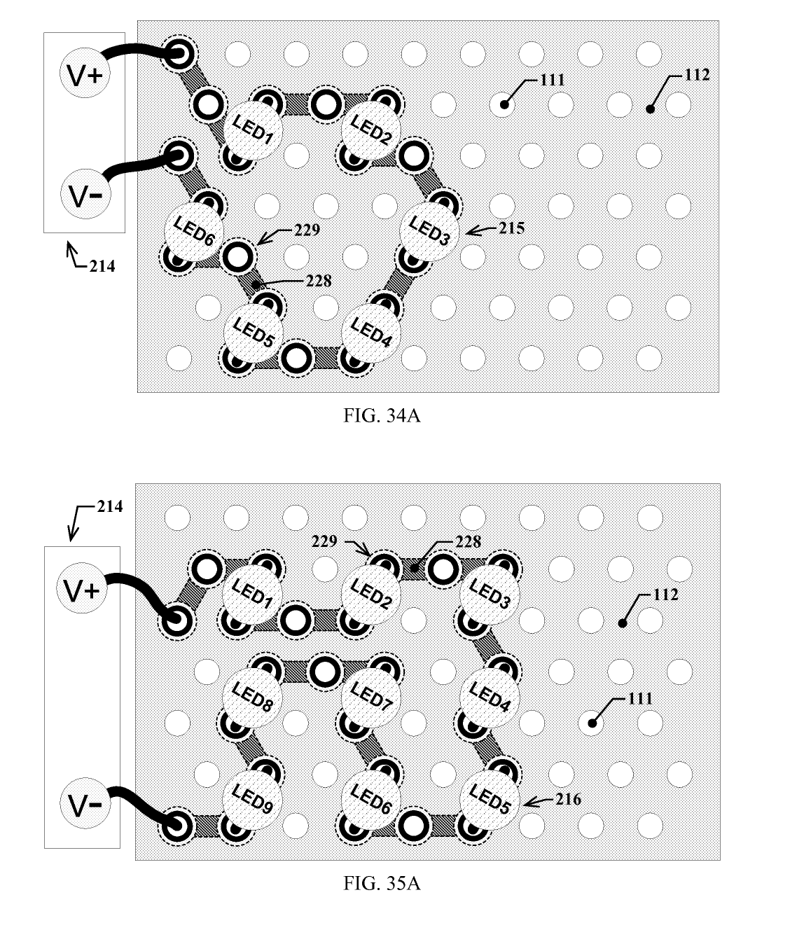

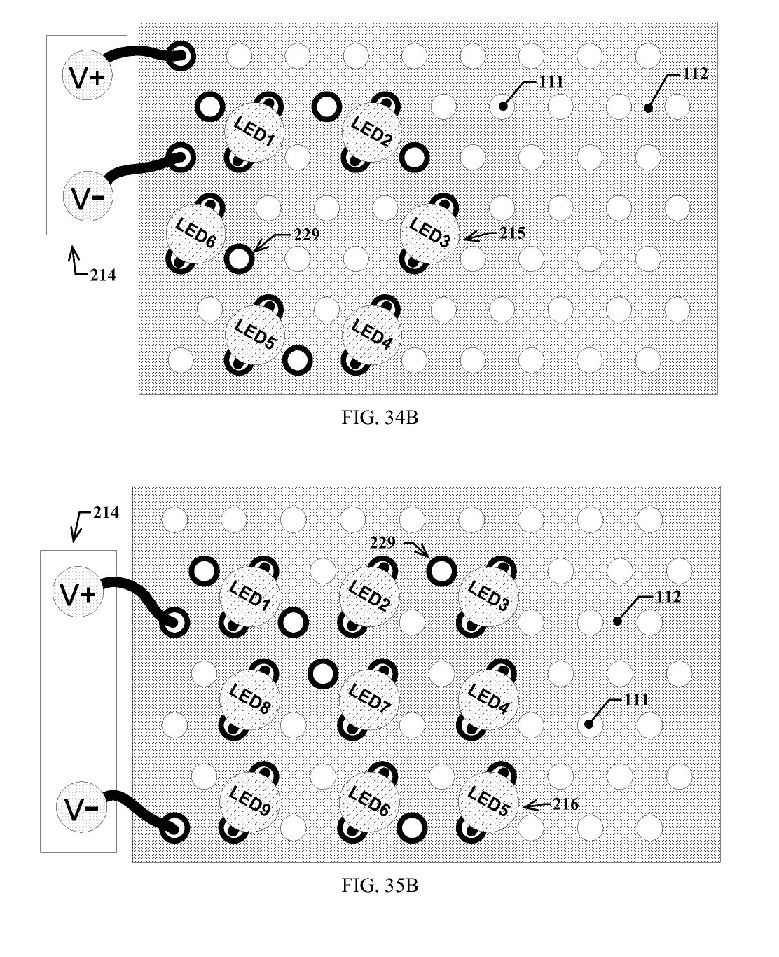

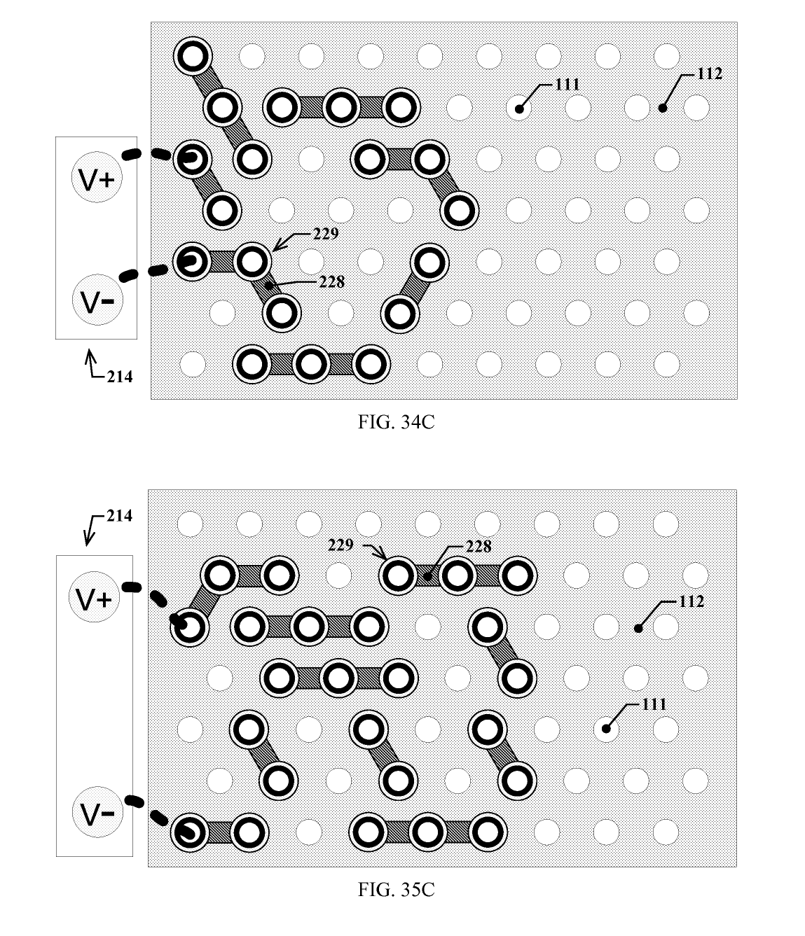

FIG. 34-FIG. 55 illustrate various example SpinBoard and SpinConnector assemblies, some of which include for example a perforated board, a power supply, SpinConnectors, and electronic components. In general, the various illustrated components in each of these figures may be adapted to a wide variety of purposes. For example, as discussed above, the perforated board may be made of a flat, rigid material, or of flexible material and/or a shaped material as desired. In the case of a flexible or shaped perforated board material, SpinConnector plates may be sized and shaped appropriately. For example, plates designed for placement on a convex side of a curved perforated board surface may be longer than plates designed for placement on a concave side of a curved perforated board surface. Also the plates may be curved or straight. This design may allow appropriately placed plates to hold the perforated board in a desired curved shape. FIG. 34-FIG. 35 and FIG. 37-FIG. 54 use equilateral triangle grid aperture patterns with a property that each aperture (except those at the border) is surrounded by six equidistant neighbors. In the case of FIG. 46, a subset of the apertures is included, but those apertures retain positions according to the equilateral triangle grid pattern.

The perforated board 112 may be designed to accommodate any number of circuits and may include power supply controls for independent and/or collective control of the circuits. Circuits can overlap one another. At a point of overlap, a plate associated with a first circuit may be placed on an opposite side of the perforated board 112 as a plate associated with a second circuit to avoid conductive contact between the circuits. Another overlap technique can use an isolation sheet, for example, a sheet with a similar aperture pattern as perforated board 112, which can be placed over a first circuit or portion thereof to isolate a second circuit that overlaps the first circuit. An isolation sheet may for example be made of a flexible, transparent, electrically insulating material such as plastic and may be the size of a perforated board surface, or may be sized smaller than the perforated board surface to patch over a desired overlap region. Another overlap technique can use plates which are electrically insulated on the bridge portion between pin receptacles, thereby allowing plate bridges to touch without making conductive contact. Plate bridges may be insulated for example using heat-shrinking insulation tubes.

Pins associated with various SpinConnectors may be inserted into apertures such as 111 in the perforated board 112, as well as into pin receptacles in plates associated with the SpinConnectors. The plates and electronic components may be disposed on either or both sides of the perforated board 112. The various pins may be held in place in the perforated board 112 by friction. The pins may also be glued, snapped, or otherwise affixed in place in some embodiments. In some embodiments, the SpinConnectors may be manually pulled from the perforated board 112 and placed in other apertures, with appropriate plates in position to change the shape of a circuit. Conductive contact between terminals of electronic components, pins, and plates may be friction-based, or may be reinforced by soldering, crimping, glue, and so forth. Electronic components such as LEDs 215 and 216 may be easily replaced in some embodiments to suit the desired properties of a configurable LED bulb, or other circuit as may be constructed on the perforated board. [0057] FIG. 34-FIG. 35 illustrate an example perforated board 112 comprising a plurality of apertures such as 111, and adapted for use as a configurable LED bulb in two different configurations. FIG. 34 comprises a configuration according to the circuit of FIG. 30, while FIG. 35 comprises a configuration according to the circuit of FIG. 31. It will be appreciated that any number of other circuit variations are possible.

FIG. 34A and FIG. 35A show all the aspects of the completed circuit, including power supply 214, plates such as 228, pins such as 229, and electronic components such as LEDs 215 and 216. FIG. 34B and FIG. 35B show the power supply 214, pins such as 229, and electronic components such as LEDs 215 and 216, as may in some embodiments be visible from a top view of a SpinBoard assembly. FIG. 34C and FIG. 35C show the power supply 214, plates such as 228, and pins such as 229, as may in some embodiments be visible from a bottom view of a SpinBoard assembly.

An LED bulb constructed according to the techniques described herein is desirable in part due to the efficiency and very low electromagnetic field (EMF) emissions of LED lighting. An LED bulb may comprise one or several LEDs that are connected in series and/or in parallel configurations. The LEDs are easily reconfigurable in terms of color configurations, positions of the LEDs, and number of LEDs. Additional properties such as programmable flashing, adjustable brightness and the like are also achieved. Such an LED bulb can be advantageously applied in home or office lighting, light therapy and other applications.

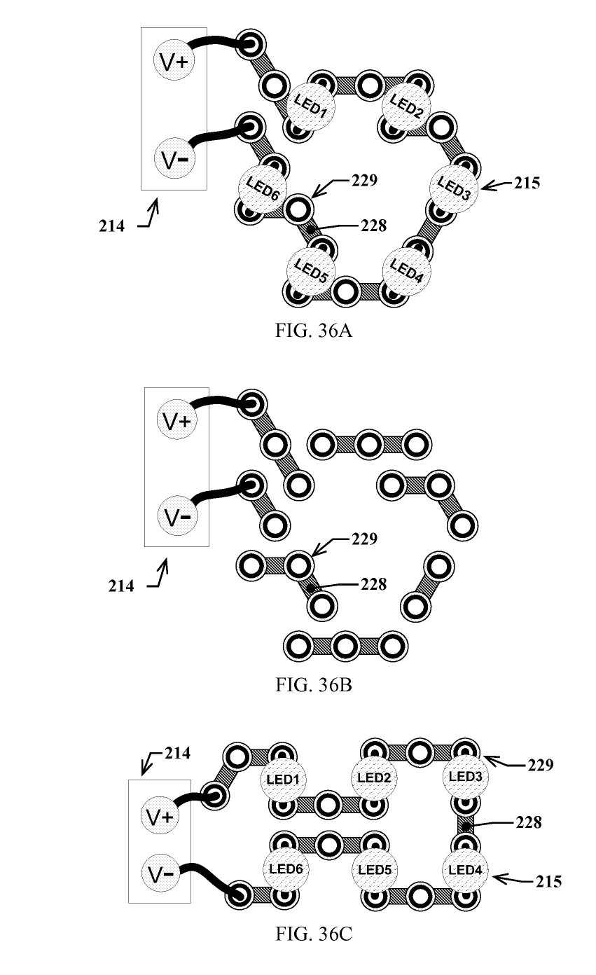

FIG. 36 illustrates a SpinConnector assembly which does not make use of a perforated board. FIG. 36A illustrates a top view of an example SpinConnector assembly. FIG. 36A illustrates the components of FIG. 34A, including power supply 214, pins such as 229, plates such as 228 and electronic components 215, but without the perforated board 112 and associated apertures 111. FIG. 36B illustrates a top view of an example SpinConnector assembly with certain elements removed to better illustrate the remaining elements. FIG. 36B illustrates power supply 214, pins such as 229, and plates such as 228, while the electronic components 215 are removed, and again without the perforated board 112 and associated apertures 111.

FIG. 36C illustrates the elements of FIG. 36A and FIG. 36B which have been realigned by articulating the joints as illustrated. Here, some or all of the pins may serve as joints allowing articulation. The round pin and pin receptacle structure allows realignment to any angle. In some embodiments, an oval/polygonal pin and/or pin receptacle may be used to restrict allowable articulation angles.

FIG. 36A, FIG. 36B, and FIG. 36C illustrate that a perforated board is not necessary in all embodiments. Embodiments not including a perforated board are referred to herein as SpinConnector assemblies. Using SpinConnector assemblies, the SpinConnectors and electronic components can be configured in a same layout as might otherwise be achieved with the use of a perforated board, if desired, but may also be configured without restrictions imposed by perforated board aperture patterns. The various joints can be articulating or at fixed orientations, to provide reorientable or non reorientable structures, respectively.

Reshapeable applications are a particularity of SpinConnector assemblies without a perforated board, as illustrated by the LED electronic circuit chain from FIG. 36. Such reshapeable electronic circuits are appropriate for installing in hardware that is allowed to adjust its shape during operation, such as in robotics.

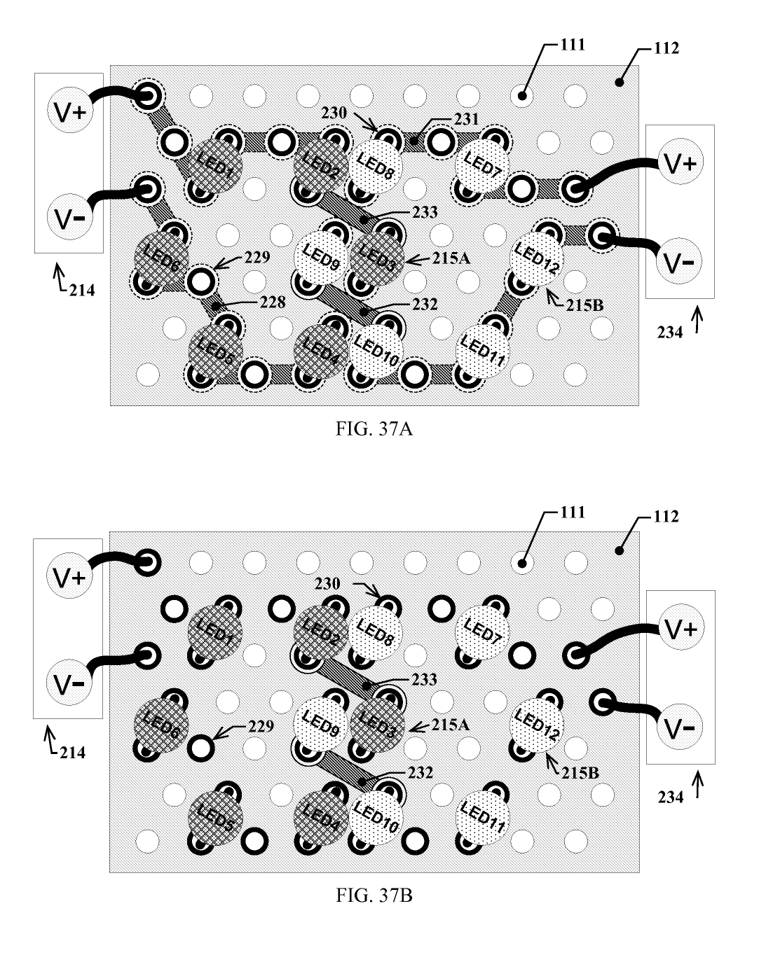

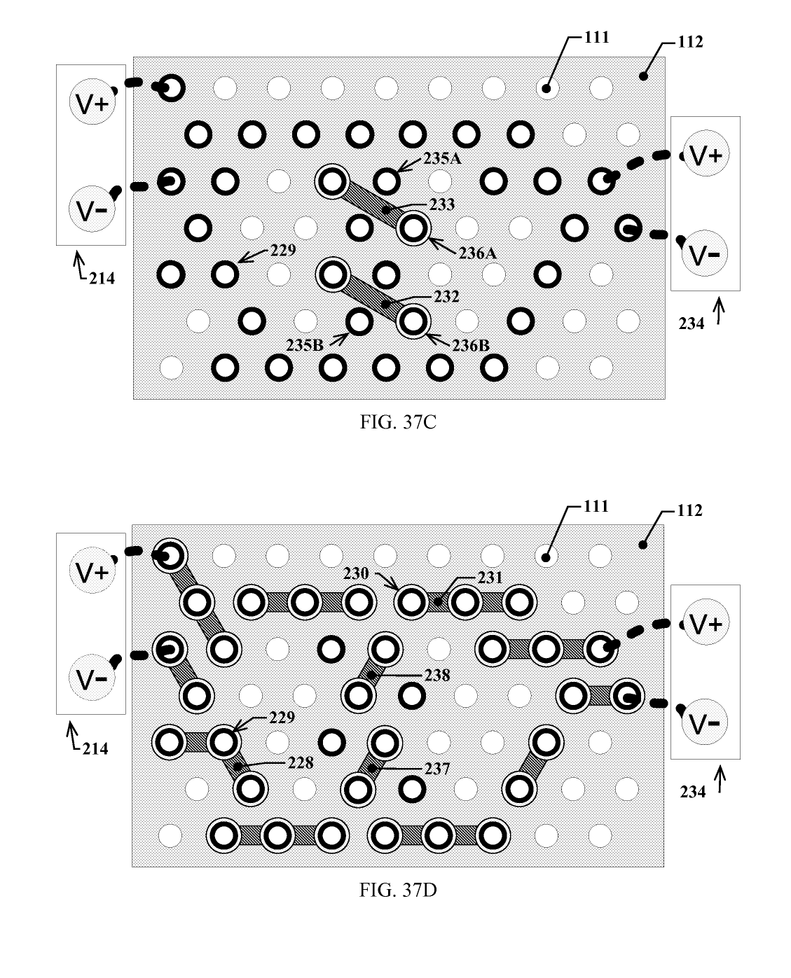

FIG. 37-FIG. 39 illustrate example SpinBoard assemblies comprising overlapping circuits. FIG. 37 comprises two circuits according to FIG. 30, while FIG. 39 comprises a circuit according to FIG. 31, and another similar circuit comprising just four LEDs electronic components.

FIG. 37A illustrates a view of an example SpinBoard assembly showing all elements as may be disposed on either surface of a perforated board. FIG. 37A comprises a perforated board 112 with apertures such as 111 and many elements of a first circuit similar to the circuit shown in FIG. 34, with like elements given like identifiers. The first circuit in FIG. 37A includes LEDs such as 215A, including LED1-LED6, connected to power supply 214. The first circuit in FIG. 37A also includes and also includes plate 233 in place of a corresponding SpinConnector structure shown in FIG. 34. FIG. 37A furthermore comprises a second circuit, comprising LEDs such as 215B, including LED7-LED12, connected to power supply 234. The second circuit also comprises example pin 230 and example plates 231 and 232.

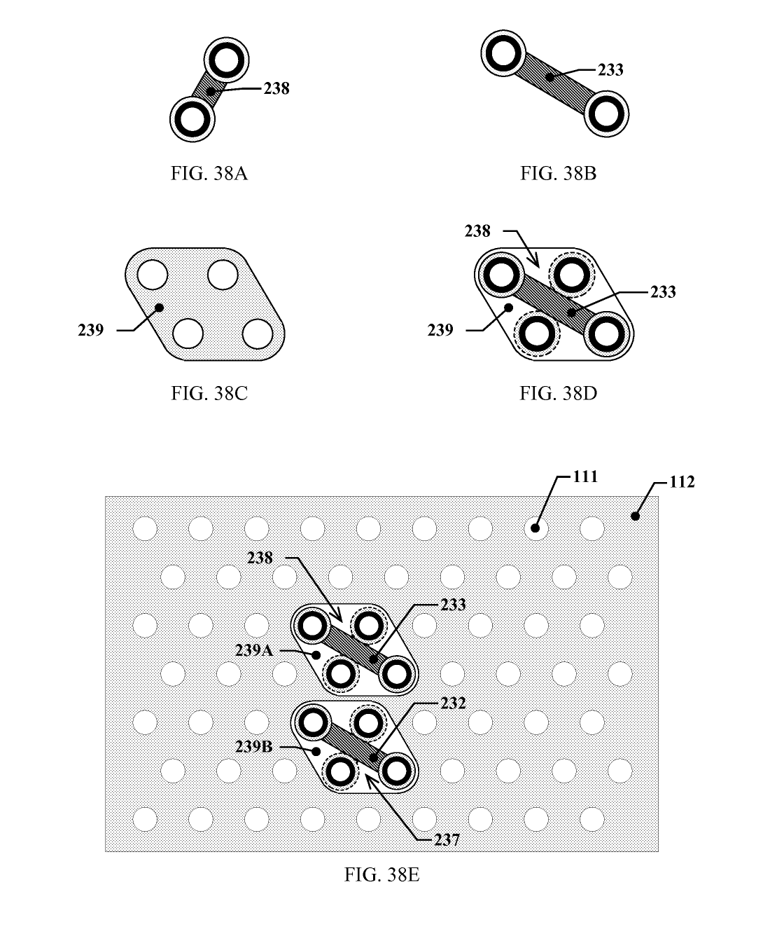

In FIG. 37A, all aspects of the provided SpinBoard assembly are shown. Plates 233 and 232 are disposed on a first surface of perforated board 112, while the remaining plates such as 228 and 231, and also plates 238 and 237 as illustrated in FIG. 37D, are disposed on a second surface of perforated board 112, to allow overlapping of circuit traces. Plate 233 overlaps plate 238 connecting LED8 with LED9 on the second circuit. Plate 232 overlaps plate 237connecting LED3 with LED4 on the first circuit. In example alternative arrangements, plates 233 and 232 can be on a same side as the other plates, so long as they are properly insulated, for example using an isolation sheet, as illustrated in FIG. 38, or by electrically insulated plates as described herein.

FIG. 37B shows aspects of the provided SpinBoard assembly that are disposed on a first surface of the perforated board 112, as may be visible from a top view of the SpinBoard assembly. This includes plates 231 and 233, as well as LEDs such as 215A and 215B, and those portions of pins 229 and 230 disposed at or near the first surface.

FIG. 37C also shows aspects of the provided SpinBoard assembly that are disposed on a first surface of the perforated board 112, except that the LEDs 215A and 215B are removed to provide a better view of plates 232 and 233, showing that in this example there is no conductive contact between plates 232 and 233 and neighbor pins 235A and 235B. However, conductive contact is maintained between the elements of the respective SpinConnector structures, such as plates 232 and pin 236B, and plate 233 and pin 236A.

FIG. 37D shows aspects of the provided SpinBoard assembly that are disposed on a second surface of the perforated board 112, as may be visible from a bottom view of the SpinBoard assembly. Example plates such as 228, associated with the first circuit, and example portions of pins at or near the second surface, such as pin 229, are shown. Also, example plates such as 231, associated with the second circuit, and example portions of pins at or near the second surface, such as pin 230, are shown.

FIG. 38 illustrates the use of an isolation sheet in the form of an isolation patch. FIG. 38A illustrates an example top view of a first SpinConnector structure comprising a plate 238 as illustrated in FIG. 37D. FIG. 38B illustrates an example top view of a second SpinConnector structure comprising a plate 233 as illustrated in FIG. 37C. FIG. 38C illustrates an example top view of an isolation patch 239 with four holes corresponding to the pins associated with the SpinConnectors illustrated in FIG. 38A and FIG. 38B. FIG. 38D illustrates an example transparent top view of an arrangement in which plate 238 is separated from plate 233 by isolation patch 239. The patch 239 is disposed between the plates 238 and 233, to form a conductive barrier between the plates 238 and 233.

The example isolation patch 239 may be extended to any size up to and including all of the apertures of a SpinBoard assembly. The example isolation patch 239 allows for circuit overlap on a same side of a perforated board. An isolation sheet may also serve as a very thin perforated board structure in some embodiments. For example, an isolation sheet may be used in connection with embodiments such as illustrated in FIG. 36, and in connection with flexible and non-planar SpinBoard assemblies.

FIG. 38E illustrates an example use of the isolation patch 239, as illustrated in FIG. 38, in the context of a SpinBoard assembly such as provided in FIG. 37. In FIG. 38E, all of the components of FIG. 37 are removed except plates 238, 233, 237, and 232. Furthermore, plates 238, 233, 237, and 232 are disposed on a same side of a perforated board 112 in FIG. 38E. Isolation patches 239A and 239B prevent conductive contact between plates 238 and 233 and plates 237 and 232, respectively, allowing the use of non-insulated plates on a same side of perforated board 112.

FIG. 39A illustrates a view of an example SpinBoard assembly showing all elements as may be disposed on either surface of a perforated board. FIG. 39A comprises a perforated board 112 with apertures such as 111 and many elements of a first circuit similar to the circuit shown in FIG. 35, with like elements given like identifiers. The first circuit in FIG. 39A includes LEDs such as 216A comprising LED1-LED9 connected to a power supply 214.

FIG. 39A furthermore comprises a second circuit, comprising LEDs such as 216B, including LED10-LED13, connected to power supply 234. The second circuit is similar to the circuit illustrated in FIG. 35, with four LEDs connected in series instead of nine. The second circuit comprises pins such as 241 and plates such as 240 and 242.

In FIG. 39A, all aspects of the provided SpinBoard assembly are shown. In some embodiments, plates of the second circuit such as 240 and 242 may be disposed on a first surface of perforated board 112, while the plates of the first circuit 228 may be disposed on a second surface of perforated board 112, to allow overlapping of circuit traces. For example, plate 240 of the second circuit may overlap plate 245 connecting terminal of LED4 and LED5 on the first circuit. Also, a SpinConnector associated with plate 247 (illustrated in FIG. 39D) between terminals of LED1 and LED2 on the first circuit may share an aperture with a pin 244 on the second circuit associated with LED11, as discussed further below. In example alternative arrangements, plates of either circuit can be on a same side as the plates of the other circuit, so long as they are properly insulated, for example using an isolation sheet or by electrically insulated plates as described herein.

FIG. 39B shows aspects of the provided SpinBoard assembly that may be disposed on a first surface of the perforated board 112, as may be visible from a top view of the SpinBoard assembly. This includes plates of the second circuit such as 240 and 242, as well as LEDs such as 216A of the first circuit, and LEDs such as 216B of the second circuit. Also, those portions of pins 229 and 241 disposed at or near the first surface are shown.

FIG. 39C shows aspects of the provided SpinBoard assembly that may be disposed on a first surface of the perforated board 112, with the LEDs removed to provide a better view of the plates and pins. The terminals of LED11 in FIG. 39A and FIG. 39B are inserted into pins 243 and 244. Pins 243 and 244 may be inserted from the first surface of the perforated board 112. Because the apertures in which pins 243 and 244 are shared with plates 246 and 247 from FIG. 39D, pins 243 and 244 may be shorter than the full length of the apertures, preventing conductive contact between pins 243 and 244 of the first circuit and plates 246 and 247 of the second circuit. For example, structures such as illustrated in FIG. 12 and FIG. 13 may be used.

FIG. 39 illustrates two general overlap techniques. In a first technique, a plate such as 240 may bridge between non-neighbor pins. In a second technique, an aperture may be shared by two circuits, by using for example pins such as 243 and 244 and plates such as 246 and 247.

FIG. 39D shows aspects of the provided SpinBoard assembly that may be disposed on a second surface of the perforated board 112, as may be visible from a bottom view of the SpinBoard assembly. Example plates such as 228, associated with the first circuit, and example portions of pins at or near the second surface, such as pin 229, are shown. Plates 246 and 247 may comprise for example a three pin receptacle configuration. In such embodiments, no pin need be inserted in the center pin receptacle. Instead, the presence of a center pin receptacle can avoid conductive contact between the plates 246 and 247 and terminals of an electronic component such as LED11, which may pass through the board 112 as well as through a plate such as 246 or 247, without making conductive contact with the plate.

In some embodiments, short pins not touching pins 243 and 244 may be inserted into the center receptacle of plates 246 and 247. In some embodiments, plugs 136A and 136B may be inserted into the center receptacles of plates 246 and 247. Plugs 136A and 136B and/or short pins allow mechanical attachment of a plate to a perforated board without risking conductive contact from elements on the other side of the board. A cross section of an assembly using short pins or plugs is illustrated in FIG. 12 and FIG. 13.

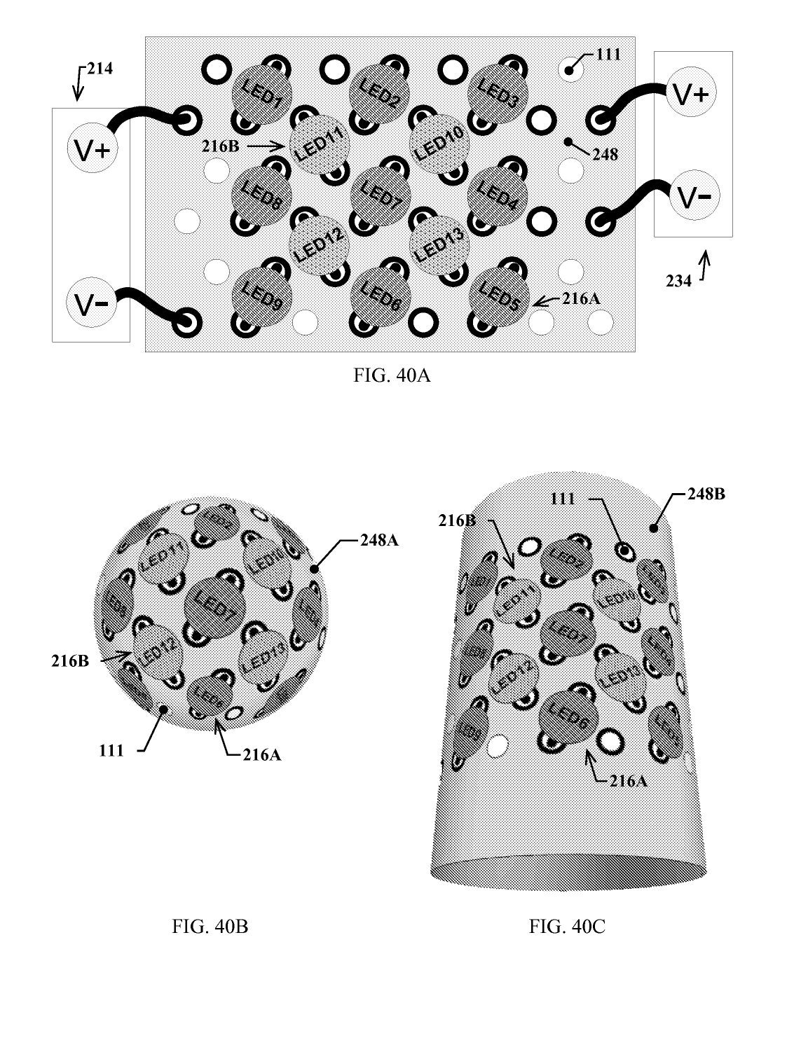

FIG. 40 illustrates example non-planar SpinBoard assemblies. FIG. 40A illustrates a planar SpinBoard assembly which is provided in non-planar forms in FIG. 40B and FIG. 40C. FIG. 40A comprises a perforated board 248 including apertures such as 111, power supplies 214 and 234, a first circuit including electronic components such as 216A and including LED1-LED9, and a second circuit including electronic components such as 216B and including LED10-LED13.

FIG. 40B and FIG. 40C illustrate the SpinBoard assembly of FIG. 40A in non-planar shapes. FIG. 40B provides a spherical SpinBoard assembly and FIG. 40C provides a cylindrical SpinBoard assembly. Perforated boards 248A and 248B may be made of a flexible material such as soft plastic or rubber allowing deformation, or may be made of a rigid material such as hard plastic which is fixed in a given non-planar shape. Non-planar shapes as illustrated may be advantageously used for a variety of functional goals. For example, in configurable LED bulb embodiments, non-planar shapes allow for better dispersion of light. Other applications in which non-planar circuits are preferable include those requiring better use of available space such as in robotics and field applications in which large flat surfaces may not be available.

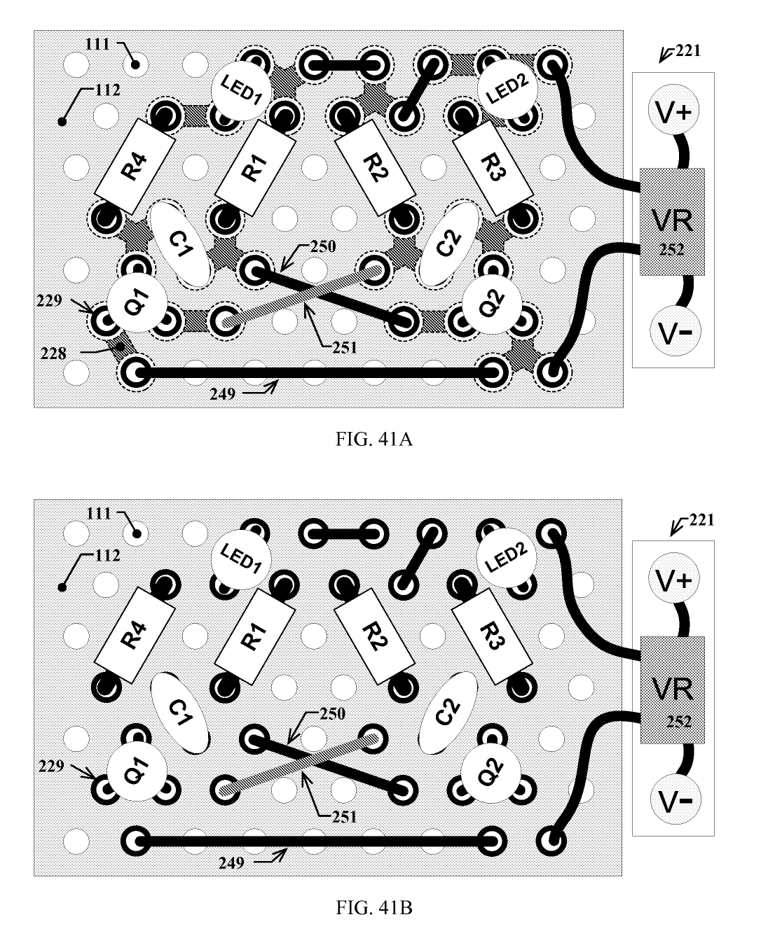

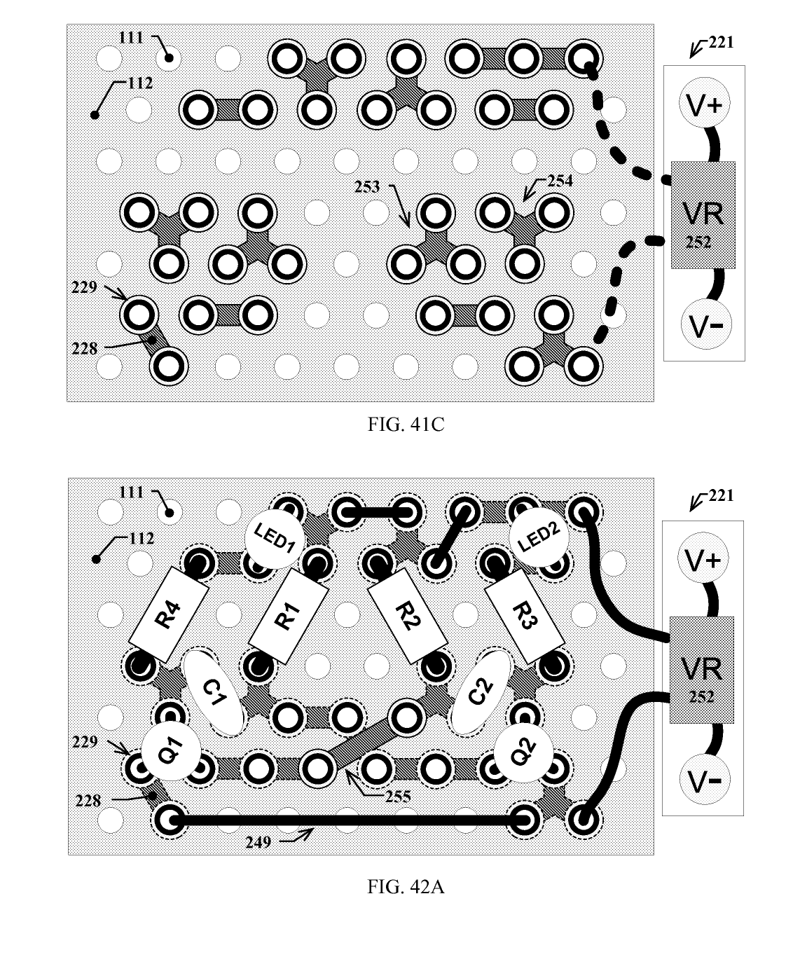

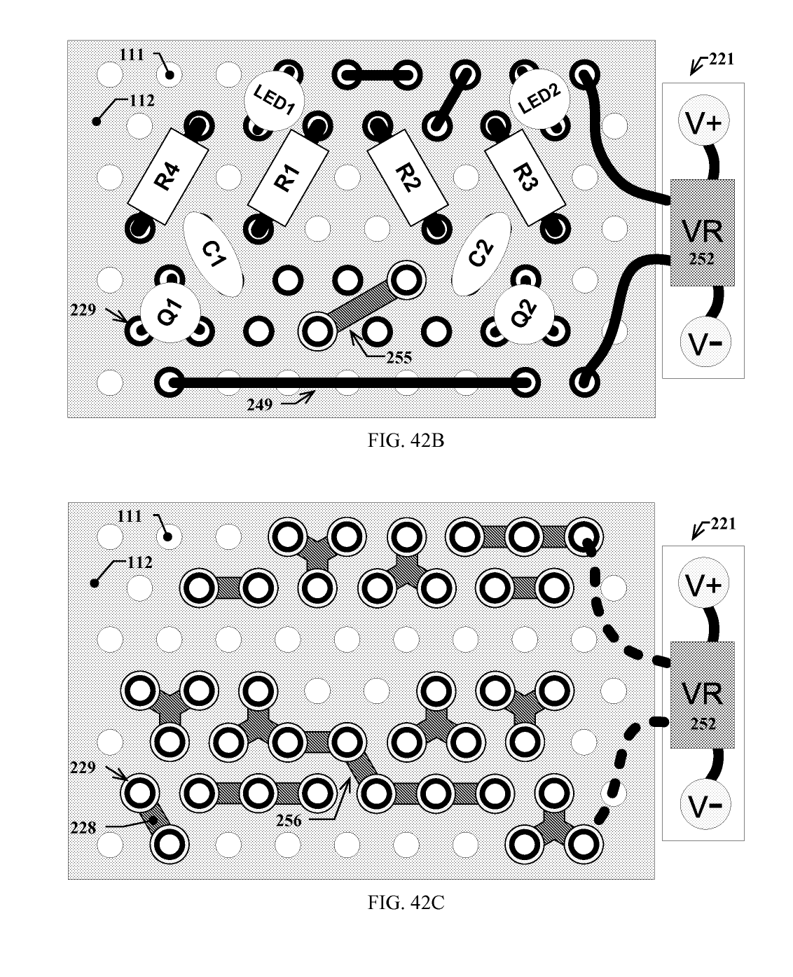

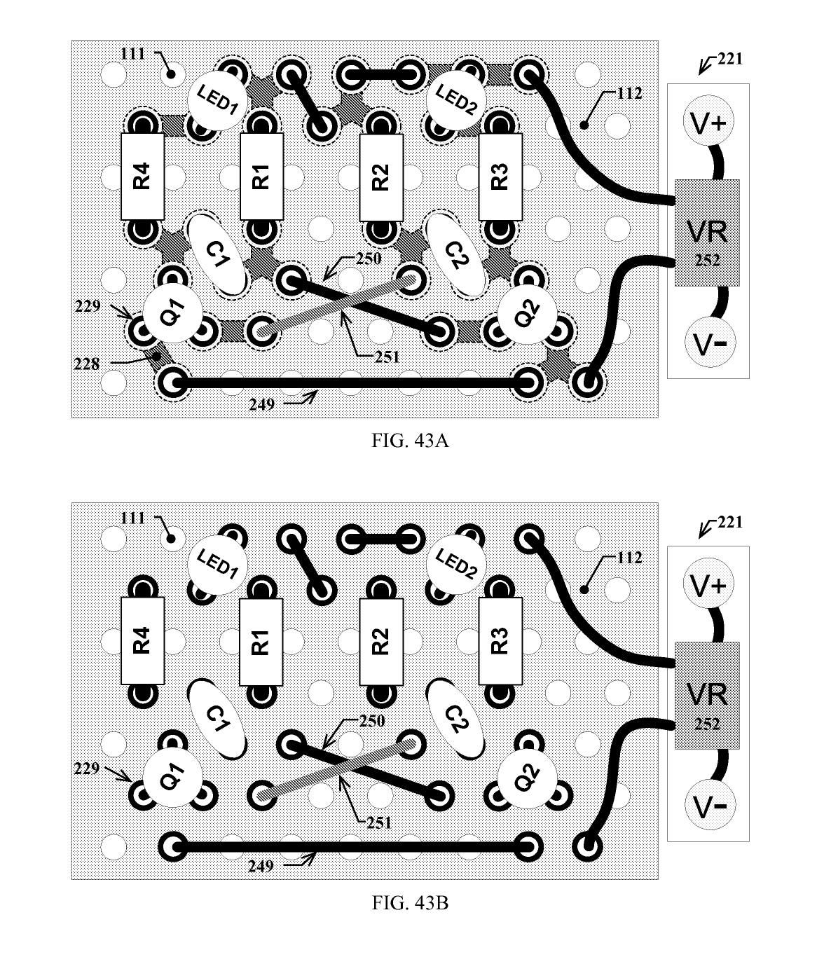

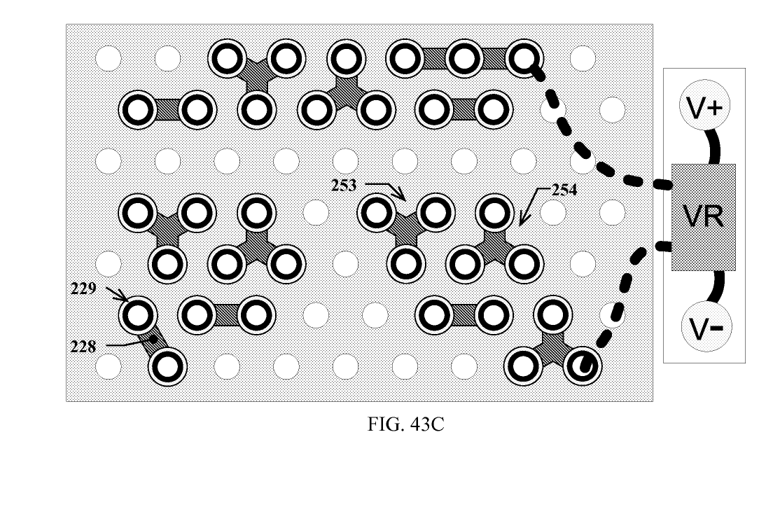

FIG. 41-FIG. 43 illustrate an example perforated board 112 fitted with an alternating flash circuit according to the circuit of FIG. 32. FIG. 41A, FIG. 42A and FIG. 43A each show all the aspects of a completed circuit, including power supply 221, voltage regulator 252, plates such as 228, pins such as 229, and electronic components such as LED 217, resistor 220, capacitor 218 and transistor 219, as may be disposed on either surface of a perforated board. FIG. 41B, FIG. 42B and FIG. 43B show the power supply 221, voltage regulator 252, pins such as 229, and electronic components 217, 220, 218 and 219, as may be visible in an example top view of a SpinBoard assembly, with certain elements removed to better illustrate the remaining elements. FIG. 41C, FIG. 42C and FIG. 43C show the power supply 221, voltage regulator 252, plates such as 228, and pins such as 229, as may be visible in an example bottom view of a SpinBoard assembly.

The voltage regulator 252 may in some embodiments be equipped with a current regulator and a fuse or circuit breaker for safety of the assembly.

In FIG. 41, there is a jump wire 250 forming an electrical connection between capacitor/resistor C1/R1 and Q2. Similarly, there is a jump wire 251 forming an electrical connection between capacitor/resistor C2/R2 and Q1. The circuit also makes use of other jump wires, for example 249. Jump wires may be used to bridge between pins. Jump wires can be a convenient way to electrically connect pins, for example where different circuits or portions of a circuit would overlap, or where a distance between pins is more conveniently spanned by a jump wire than one or more plates. Jump wires may be insulated in some embodiments—for example jump wires 251 and 250 are preferably insulated to prevent shorting. Like plates, any jump wire may be disposed on either side of the perforated board 112, and some jump wires may be on a first side while others are on the opposite side.

In FIG. 42, a combination of plates including plates 255 and 256 are used instead of the jump wires 251 and 250 of FIG. 41. FIG. 42B shows a first surface of the perforated board 112, on which plate 255 is disposed, while FIG. 42C shows an opposite surface of the perforated board 112, on which plate 256 is disposed. These plates may be on a same side of the perforated board 112 in other embodiments, using techniques discussed herein, such as by insulating portions of the plates or using an isolation sheet.

Plates of any size and shape can be included with a SpinBoard assembly, as discussed above; however in some embodiments, plates of just two lengths may be used. A first length can allow connection between two neighbor apertures, such as plate 256 in FIG. 42C, while a second length allows connection between diagonally situated apertures, such as plate 255 in FIG. 42B.

In FIG. 43, a same circuit as FIG. 41 and FIG. 42 is illustrated, in a different layout, demonstrating the flexibility of the SpinBoard design to accommodate different user preferences and design choices. FIG. 43 arranges the resistors R1-R4 vertically rather than diagonally, in addition to other layout differences, for example plates 254 and 253 in FIG. 41C are rotated in FIG. 43C. The terminals of the resistors R1-R4 are also adjusted somewhat in FIG. 43 to match the distance between the apertures. Terminals of any electronic component for use with some embodiments may be of adjustable widths apart to allow for different distances between apertures in different orientations, for example by bending the terminals at different points.

FIG. 44-FIG. 45 illustrate an example SpinBoard assembly including perforated board 112 with apertures 111 fitted with an amplifier circuit according to the circuit of FIG. 33. FIG. 44A and FIG. 45A show all the aspects of the completed circuit, as may be disposed on either surface of a perforated board, including power supply 227, plates such as 228, plate 258 or jump wire 260, pins such as 229, and electronic components such as R1, R2, R3, and integrated circuit U1. Input 222 and output 226 are also shown, with input signal wires shown as (I+), output signal wires shown as (O+), and ground connections illustrated as (I−) and (O−). FIG. 44B and FIG. 45B show power supply 227, plate 258 or jump wire 260, pins such as 229, and electronic components such as R1, R2, R3, and integrated circuit U1, as may be visible in an example top view of a SpinBoard assembly, with certain elements removed to better illustrate the remaining elements. Input 222 and output 226 are also shown. FIG. 44C and FIG. 45C show the power supply 227, plates such as 228, and pins such as 229. Input 222 and output 226 are also shown. In this example, plate 258 or jump wire 260 (illustrated in FIG. 44B and FIG. 45B) connect plates illustrated in FIG. 44C and FIG. 45C. Plate 258 or jump wire 260 could also be located on the side of the perforated board 112 illustrated in FIG. 44B and FIG. 45B, in which case plate 258 or jump wire 260 may be electrically insulated from any conductive elements they may overlap with.

FIG. 44-FIG. 45 also illustrate a single pin SpinConnector 257, which is used in the illustrated embodiment to house a terminal associated with the integrated circuit U1, which terminal is not connected to the circuit. This reinforces the mechanical connection between the integrated circuit U1 and the perforated board 112.

FIG. 44C and FIG. 45C illustrate aspects of a SpinBoard assembly may be visible in an example bottom view. FIG. 44C illustrates an example use of multi-pin SpinConnectors 166 and 188 from FIG. 21 and FIG. 23, respectively. These connectors may be bridged by a plate or jump wire 261. Similarly, FIG. 45C illustrates multi-pin SpinConnectors 168A and 168B with structure identical to connector 168 in FIG. 21. These connectors may be bridged by a plate or jump wire 262. The illustrated connector structures may also be constructed from a plurality of smaller connectors such as for example 2, 3, and 4 pin SpinConnectors which may be articulating or rigid.

FIG. 44 and FIG. 45 illustrate a same circuit in different layouts with respect to the apertures of a perforated board. The apertures of the perforated board illustrated in FIG. 45 are rotated 60 degrees as compared to the apertures of FIG. 44. The equilateral triangle-based aperture pattern is present in both figures. The rotation of the apertures leads to differences in circuit layout. These example layouts may accommodate user preference in circuit design, and in some cases may allow for circuit design optimization, for example where circuit design aspects such as distances between components, trace length, and overall circuit size and shape are critical.

FIG. 46A, FIG. 46B, FIG. 46C and FIG. 46D illustrate an example SpinBoard assembly, with a same electric circuit as FIG. 45. FIG. 46A generally provides many of the same elements as FIG. 45A, and like elements are given like identifiers. FIG. 46B generally provides many of the same elements as FIG. 45B, and like elements are given like identifiers. FIG. 46C generally provides many of the same elements as FIG. 45C, and like elements are given like identifiers. FIG. 46D shows only perforated board 264 with apertures such as 111, without the SpinConnectors and electronic components of the other figures.

In FIG. 46, a perforated board 264 includes a subset of the apertures of perforated board 112. The aperture subset may be selected as for example only those apertures that are used by a particular electric circuit. The perforated board 264 may be advantageous in manufacturing as the subset of apertures guides proper installation of SpinConnectors and electronic components. Also, a perforated board with fewer apertures may in some cases be manufactured more quickly and at less expense.

FIG. 46 also illustrates example SpinConnectors which include a subset of pin receptacles. For example, plate 263 does not include a pin receptacle for pin 259 from FIG. 45. Also, plate 265 replaces plates 168A, 168B, and 262 from FIG. 45. For mass producing particular SpinBoard assemblies, it may be more efficient to make only those pin receptacles that are necessary for the circuit.

FIG. 46E, FIG. 46F, and FIG. 46G illustrate an example multilayer SpinBoard assembly. In multilayer SpinBoard assemblies, the layers may have isolating and/or conductive properties. Examples of layers with conductive and isolating properties are copper clad boards. FIG. 46E illustrates an example middle layer, FIG. 46F illustrates an example top and/or bottom layer, and FIG. 46G illustrates an example cross section. In FIG. 46E a middle layer 267 may comprise different materials than other layers of the multilayer SpinBoard assembly. For example, middle layer 267 may comprise a conductive material such as copper or a copper clad board as used in the field of printed circuit board manufacture. Middle layer 267 may serve as a ground plane in some embodiments, which helps minimize electromagnetic interference in circuits built on the SpinBoard assembly. In embodiments in which middle layer 267 is conductive, it may be advantageous to use apertures in the middle layer 267, such as example aperture 266, which comprise a larger diameter than apertures in one or more other layers of the SpinBoard assembly. The dark rings illustrated in the apertures 266 in FIG. 46E show the difference between the diameters of apertures 266 and the diameters of apertures in one or more other layers of the SpinBoard assembly. Certain embodiments may utilize conductive contact with a middle layer 267, in which case diameters of certain middle layer apertures may be equal to or smaller than diameters of apertures disposed in other layers, allowing for example conductive contact between SpinConnector pins and a middle layer 267.

FIG. 46F illustrates a top and/or bottom layer 268A of a multilayer SpinBoard assembly. The SpinBoard assembly comprises apertures such as example aperture 111. The dotted lines around apertures 111 indicate the larger diameter of apertures 266 disposed in the middle layer 267 illustrated in FIG. 46A. The line 269 shows a location of a cross section slice depicted in FIG. 46G.

FIG. 46G illustrates a cross section view of a SpinBoard assembly 264. SpinBoard assembly 264 comprises layer 268A, middle layer 267, and layer 268B. Any of the illustrated layers may be made of materials different than the other layers. Furthermore, SpinBoard assemblies may include any number of layers as needed for particular implementations. Apertures 111 may be of different diameter than apertures 266, as shown.

In multilayer SpinBoard embodiments, SpinConnector plates may be disposed on any side of any layer. For example, in an embodiment in which layer 267 is not conductive, SpinConnector plates may be disposed over top layer 268A, under bottom layer 268B, as well as between top and bottom layers 268A and 268B and middle layer 267. Furthermore, pins adapted for multilayer SpinBoard assemblies, as illustrated in FIG. 19 and FIG. 20, may be used in connection with multilayer SpinBoard assemblies.

FIG. 46H illustrates a SpinBoard assembly defining a circuit board with plates affixed thereto as circuit traces. Unlike traditional printed circuit board manufacture, embodiments such as illustrated in FIG. 46H may be made by affixing plates to a board rather than by etching a board. Here, plates such as 270, 273, and 272 may be affixed to a non-conductive portion of a board 264 surface. For example, the entire board surface may be non-conductive in FIG. 46H. Plates such as 270, 273, and 272 may be affixed to board 264 for example using a same approach as for attaching the copper layer of a copper-clad board, or using a glue, rivets, or pins such as the pins discussed herein. Furthermore, plates 270, 273, and 272 may be affixed to board 264 using pin extensions as discussed below in connection with FIG. 46I and FIG. 47-FIG. 49. Plates such as 270, 273, and 272 may include circuit points 271 and/or 229 which may include receptacles for pins and/or terminals such as receptacle 229, or conductive pads such as 271. Plate 272 is an example of a plate which may comprise a single circuit point, such as a single conductive pad, receptacle, or jack (not shown in FIG. 46H). In the case of circuit points comprising receptacles, and in embodiments making use of pin extensions, the board 264 may comprise apertures corresponding to such receptacles or extensions, and the receptacles/extensions may be aligned with the appropriate apertures in the manufacturing process.

Circuit boards such as FIG. 46H may be manufactured by a process for manufacturing circuit boards as described below. First, a set of plates (e.g. 270, 273, and 272 and the other illustrated plates) may be prepared. In some embodiments, plate preparation may comprise designing plates including plate material, plate dimensions, circuit point locations and so forth. In some embodiments, plate preparation may comprise receiving predefined plates, for example, plates of a plurality of predefined plate types, and preparing such plates for circuit board assembly by for example modifying the plates, sorting and positioning the plates for use in an assembly line, or otherwise preparing the plates.

Prepared plates may correspond to circuit traces, each plate comprising at least one circuit point such as 271 and/or 229, and each circuit point comprising a conductive pad 271 or a receptacle 229. The plates may furthermore comprise pin extensions in some embodiments. The plates may then be affixed, as described above, to a non-conductive portion of a board 264 surface. Where the circuit design calls for pins, pins may be inserted into receptacles in the plates and the corresponding apertures on the circuit board. Affixing plates to a board may be performed in a predefined assembly line sequence. Such sequence may comprise for example a mechanized sequence in which manufacturing robotics or other devices are used to assemble circuit boards. Such sequence may also comprise assembly steps performed by human assembly line workers as necessary.

Any electronic components may be affixed to the various circuit points. In general, circuit boards made according to this exemplary process may furthermore leverage any of the various structures and technologies disclosed herein.

Plates 270 and 272 illustrate plates comprising only conductive pads such as 271, while plate 273 illustrates a plate comprising both conductive pads such as 271 as well as receptacles such as 229. Any combination of conductive pads and receptacles are possible, using any number and placement of pin extensions.

FIG. 46I illustrates a top view of a circuit board including example plates 275, 276, 277, and 274, as well as other elements discussed with reference to FIG. 46H, where like elements are given like identifiers. Some or all of the illustrated plates may comprise pin extensions as illustrated further below. Furthermore, plates 277 and 274 are illustrated as comprising both pads such as 271 and receptacles such as 278. Receptacles 278 may serve as pin or terminal receptacles. In some embodiments, a pin extension may be disposed underneath a receptacle 278. In FIG. 46I a plurality of the circuit points and/or pin extensions defined by the plates may align with circuit point positions defined by the triangular grid pattern of the board.

Embodiments such as FIG. 46H and FIG. 46I allow for “green” circuit board manufacture, using fewer natural resources such as copper than traditional printed circuit board manufacture techniques. Traditional printed circuit board manufacture techniques loose copper in the etching process, while the illustrated circuit board need not waste copper through etching. Moreover, embodiments such as FIG. 46H and FIG. 46I allow for easily recycling circuit board elements such as plates, by removing and reusing the plates in subsequent assemblies.

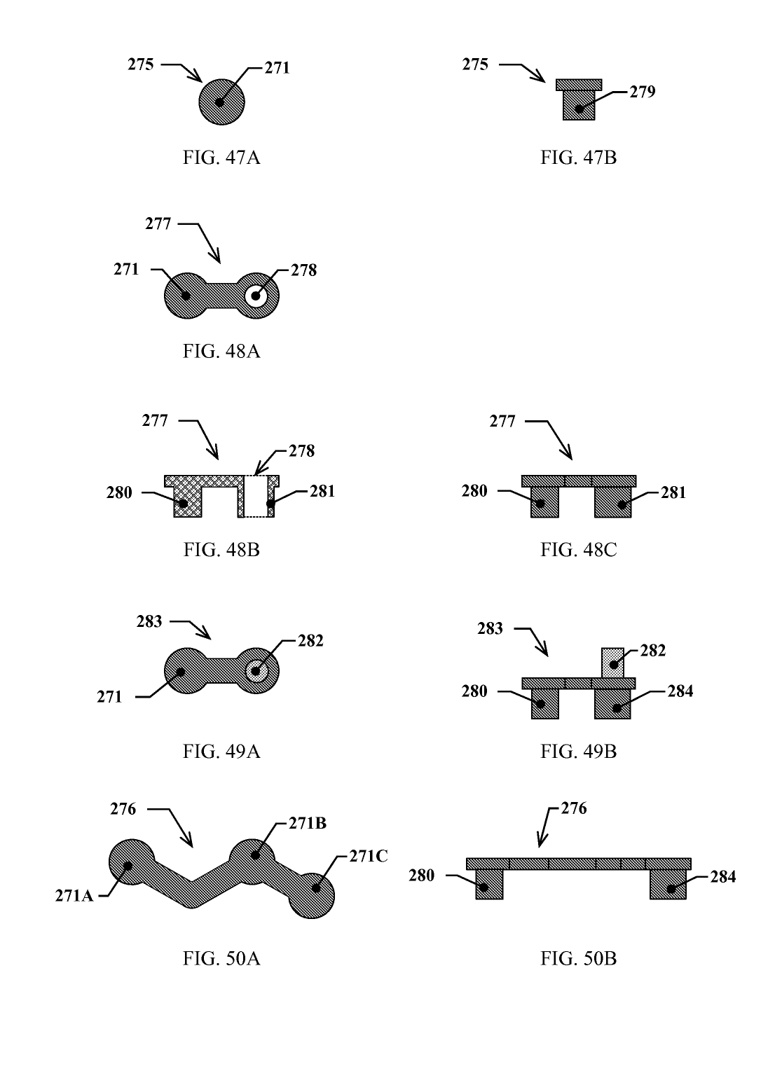

FIG. 47-FIG. 50 illustrated plates with pin extensions. Plates with pin extensions as illustrated may be considered as a variant of a SpinConnector structure in which pins and plates are formed as a single body. FIG. 47A illustrates a top view of plate 275 comprising a conductive pad 271 as illustrated in FIG. 46I. FIG. 47B illustrates a side view of plate 275, showing pin extension 279 extending from the plate 275.

FIG. 48A illustrates a top view of plate 277 comprising conductive pad 271 and receptacle 278, as illustrated in FIG. 46I.

FIG. 48B illustrates a cross section view of plate 277, showing two pin extensions. Pin extension 280 is an example solid pin extension not comprising an internal cavity. Pin extension 281 is an example pin extension including a receptacle 278 and an internal cavity defined by pin extension sidewalls, as illustrated. Receptacle 278 may receive electronic component terminals and/or pins, may allow for conductive contact between such elements and the plate 277, and may include any other aspects of receptacles as discussed herein. Pin extensions 280 and 281 may include contact elements, cap structures, may be designed for multilayer boards such as by including isolation boundaries and the like, or may include any other aspects of pins as discussed herein. Pin extensions may furthermore have different diameters, as illustrated. Pin diameter and other pin properties such as pin shape as round, oval, polygonal etc. may correspond to aperture diameters and aperture properties of a board paired with SpinConnector structures, for example, for purposes of manufacturing specific circuit trace patterns and/or in mass production environments.

FIG. 48C provides a side view of plate 277 comprising pin extensions 280 and 281, in which the different diameters of the pin extensions is clearly visible.

FIG. 49A illustrates a top view of plate 283 comprising conductive pad 271 and conductive jack 282. A conductive jack 282 is designed to fit as a male structure into a corresponding female structure disposed on an electronic component or may alternatively comprise a female jack structure with a cavity adapted for an audio, data, video, optical or other cable or plug structure, which may conform to any of the standard interface specifications. FIG. 49B provides a side view of plate 283 comprising pin extensions 280 and 284, and conductive jack 282.

FIG. 50A illustrates a top view of plate 276 comprising conductive pads such as example 271A, 271B, and, 271C as illustrated in FIG. 46I. FIG. 50B illustrates a side view of plate 276, showing pin extensions 280 and 284 extending from the plate 276 at circuit points defined by conductive pads 271A and 271C. As illustrated, pin extensions need not correspond to locations of circuit points. For example, in the illustrated embodiment no pin extensions extend beneath conductive pad 271B. Pin extensions 280 and 284 may furthermore be moved to positions that may not be beneath circuit points. Pin extension placement may be decided for example based on desired conductivity properties such as thermal properties (to reduce heat at certain locations) or electric properties (for example to conduct electricity to a desired location on another surface or layer of a board). In some embodiments, pin extension placement may be governed by aperture locations. For example, where apertures define an equilateral triangle based grid or other aperture pattern as discussed herein, pin extensions may be placed to correspond to such aperture pattern. In embodiments including a subset of apertures otherwise defined by a grid pattern, pin extension placement may similarly be governed by the subset corresponding to the particular embodiment.

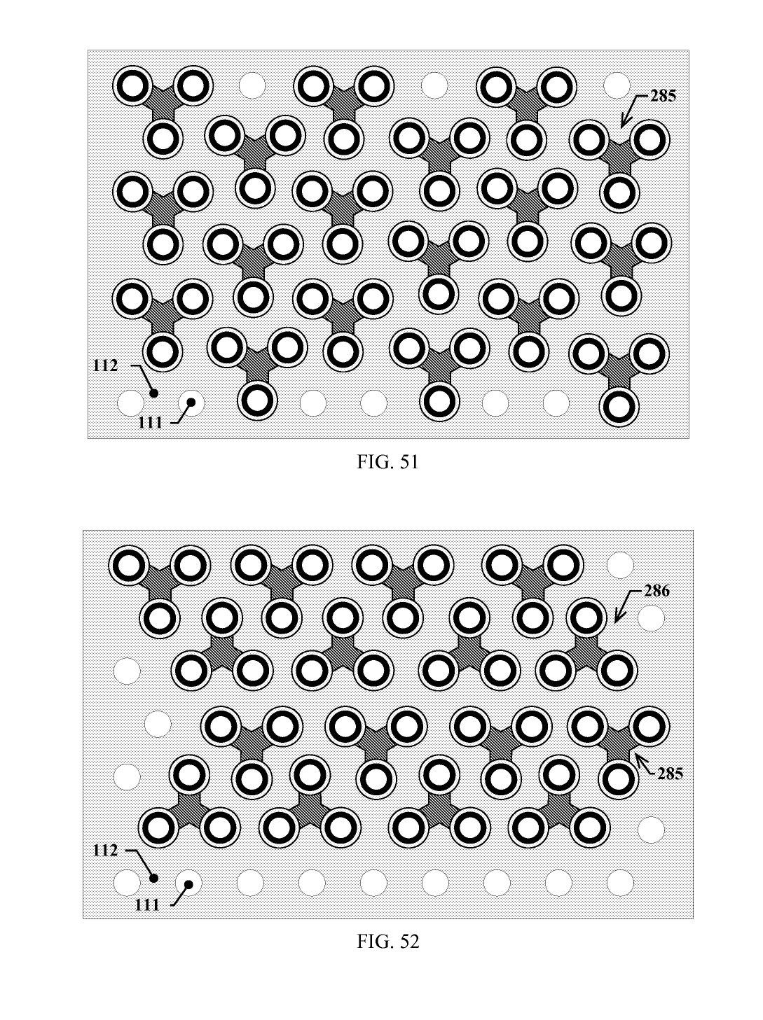

FIG. 51 and FIG. 52 illustrate an example SpinBoard assembly in which perforated board 112 has been fitted with a plurality of SpinConnectors. The SpinConnectors in FIG. 51 are all in a first orientation 285, while the SpinConnectors in FIG. 52 alternate SpinConnectors in the first orientation 285 with SpinConnectors in a second orientation 286. FIG. 52 provides an advantageous property of rows of pins belonging to alternating SpinConnectors, which may for example accommodate the terminals of an integrated circuit. In FIG. 51 and FIG. 52, distances between apertures may be scaled to be a fraction of a typical or standardized distance between integrated circuit terminals, such as one half (½), one third (⅓), or one fourth (¼) of such distance. This allows for threading traces between terminals of electronic components including integrated circuits. Sockets may be used in either embodiment to achieve desired connection patterns for integrated circuits or any other electronic component.

In both FIG. 51 and FIG. 52, almost all of the apertures (except some at the borders) are in conductive contact with certain neighbor apertures. This allows for inserting electronic components as bridges between the SpinConnectors to build a circuit. In one embodiment, a SpinBoard configured as in FIG. 51 or FIG. 52 may serve as a breadboard with predefined conductive connections between apertures. The provided breadboard arrangement has different features from the traditional breadboard layout. For example, because the SpinConnectors are interleaved as illustrated, additional flexibility in circuit design is achieved.

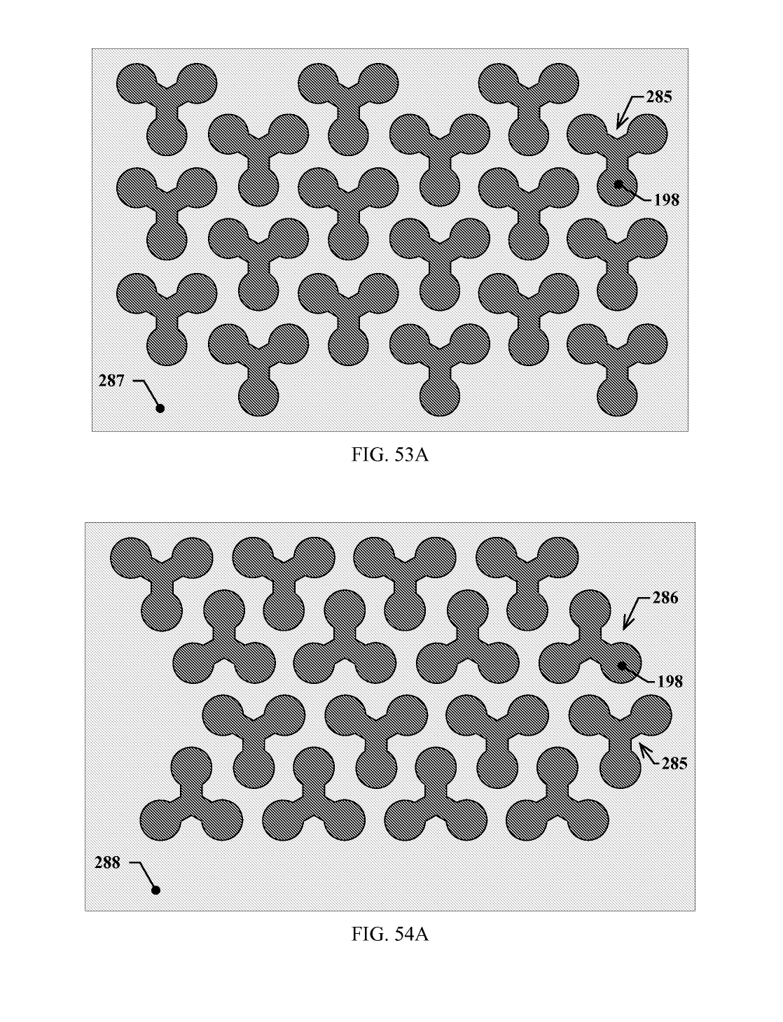

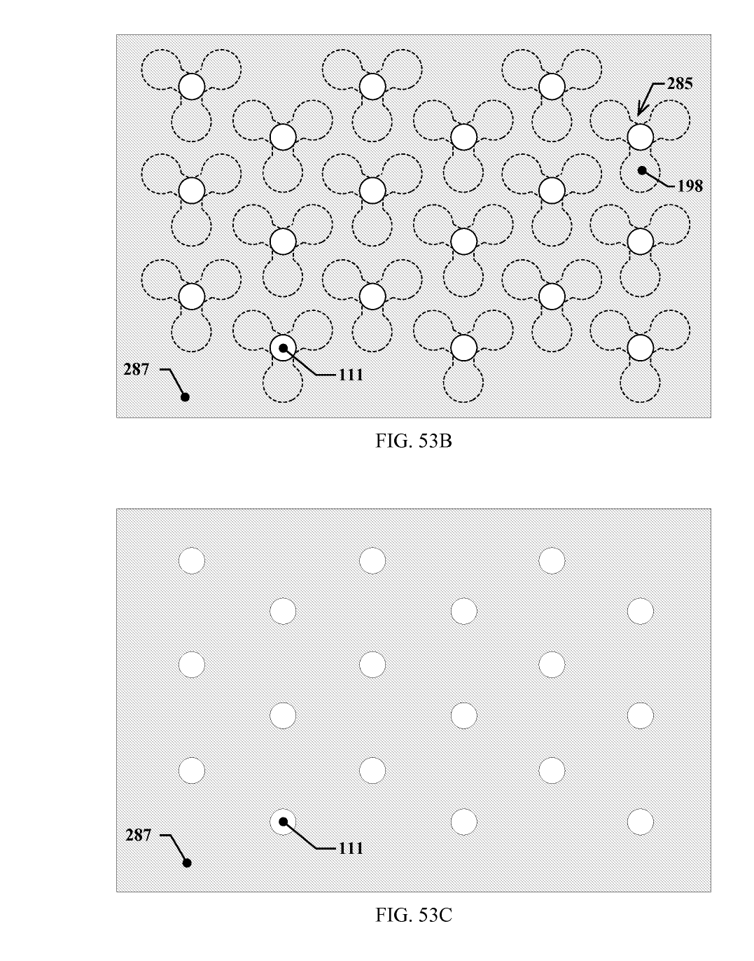

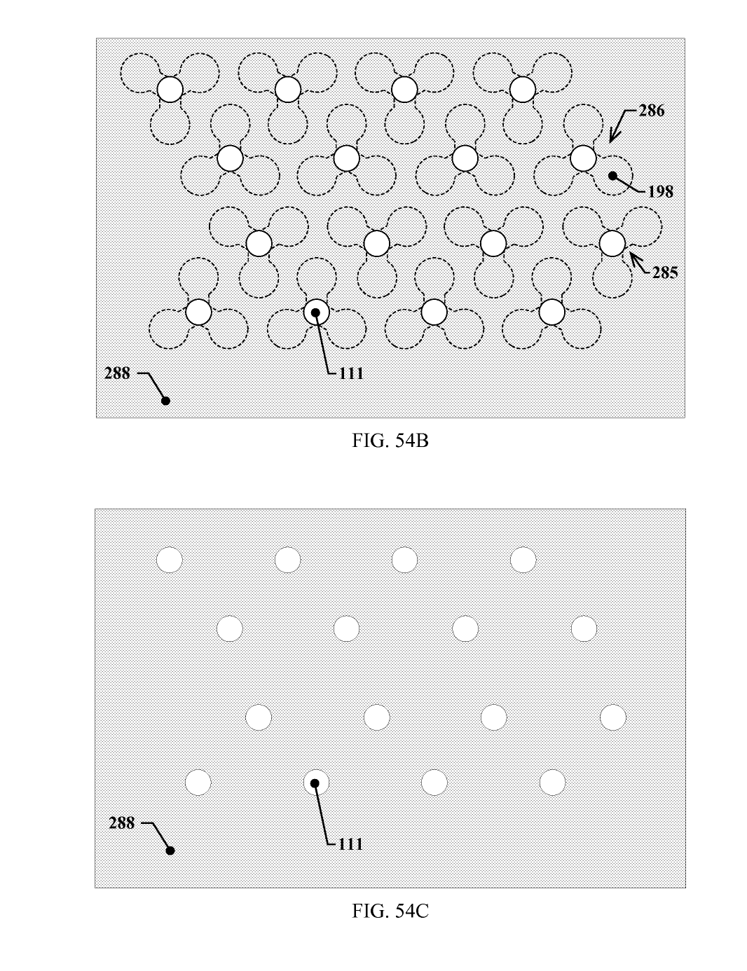

FIG. 53 and FIG. 54 illustrate example perforated boards 287 and 288 that have been fitted with a plurality of expanded cap type pins 198 as illustrated in FIG. 24. FIG. 53A and FIG. 54A illustrate a first surface of the perforated boards 287 and 288 and top view of the pins 198. FIG. 53B and FIG. 54B illustrate the first surface of the perforated boards 287 and 288 and apertures 111 in the perforated boards 287 and 288 along with dotted outlines of the top surface of the pins 198. FIG. 53C and FIG. 54C illustrate only the first surface of the perforated boards 287 and 288.

In FIG. 53 and FIG. 54, the pins 198 in FIG. 53 are all in a first orientation 285, while the pins in FIG. 54 alternate pin in the first orientation 285 with pins in a second orientation 286. FIG. 54 provides an advantageous property of rows of pins belonging to alternating pins, which may for example accommodate the terminals of an integrated circuit. In one embodiment, a perforated board configured as in FIG. 53 and FIG. 54 may serve as a breadboard with different features from the traditional quadrilateral breadboard layout, as discussed above. FIG. 53 defines an equilateral triangle grid distribution, while FIG. 54C defines a subset of apertures that may be mapped to an equilateral triangle grid. For example if an aperture were disposed inside each branch of the expansion type caps of FIG. 54B, and also at the midpoints between each three branches, an equilateral triangle based grid would result. The illustrated apertures are a subset of this set.

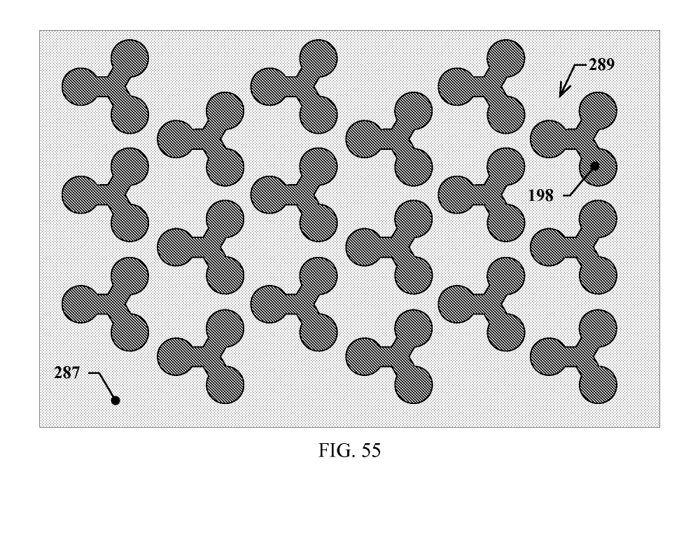

FIG. 55 illustrates an example SpinBoard assembly including a perforated board 287 which includes an aperture distribution that is the same as in FIG. 53, yet the expanded cap type pins 198 are rotated at an arbitrary angle. Here, pins 198 are rotated 30 degrees with respect to the pins in FIG. 53, so that pins 198 are in orientation 289. FIG. 55 illustrates the flexibility of the SpinBoard in orienting pins 198 as desired for particular implementations. Pin orientation may be user-configurable or predefined at time of manufacture. Expanded cap type pins of any shape may be used in embodiments similar to FIG. 55, and may be oriented at any desired angle. Similarly pin and/or SpinConnector structures of any type disclosed herein may be used in embodiments according to FIG. 55.

The illustrated pins 198 include expanded cap type pins, such as those shown in FIG. 24. In this example, a three-way branching structure is illustrated; however non-branching expanded caps and expanded caps with any number of branches are also possible. Perforated boards 287 and 288 for use with expanded cap type pins may, in some embodiments, comprise wider spacing between apertures 111. For example perforated boards 287 and 288 include one third (⅓) the number of apertures as perforated board 112. It will also be appreciated that a similar result may be achieved with a same number of apertures on a perforated board, through the use of smaller diameter apertures, or through the use of smaller caps on the expanded cap type pins.

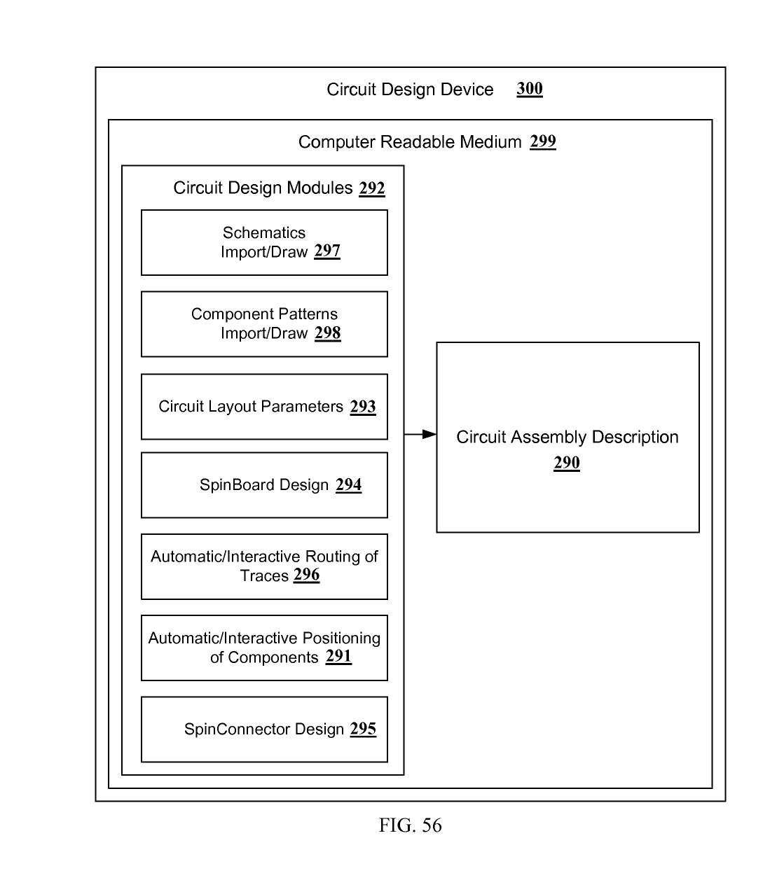

FIG. 56 illustrates a SpinBoard/SpinConnector circuit design device 300 for designing SpinBoard and SpinConnector assemblies as described herein. The design device 300 may comprise a computing device equipped with appropriate software. The design device 300 may take the form of a personal computer (PC), server computer, distributed computing arrangement, laptop, mobile device, or special purpose device as will be appreciated. In general, a design device 300 may include one or more processors (not shown), a computer readable medium 299, and a bus (not shown) for communicating between the processor and the computer readable medium 299. Depending on the desired configuration, the computer readable medium 299 may comprise any type of computer readable medium, including but not limited to volatile memory (such as RAM), non-volatile memory (such as ROM, flash memory, etc.), or any combination thereof. Computer readable medium 299 may include an operating system, one or more applications, and program data. Here, the design modules 292 may for example be included in an application for SpinBoard and/or SpinConnector design. Such circuit design modules 292 may generate a circuit assembly description 290 comprising data recorded to a computer readable medium 299.

Design modules 292 may be used to generate a circuit assembly description 290 which describes aspects of a particular SpinBoard or SpinConnector assembly. In particular, the assembly description 290 can define positions and orientations of circuit points as defined for example by pin connectors (e.g. SpinConnectors) and electronic components connected in a circuit.

Design modules 292 may include, for example, a schematic import and/or drawing module 297, a component patterns import and/or drawing module 298, a circuit layout parameters module 293, a SpinBoard design module 294, a SpinConnector design module 295, an automatic/interactive positioning of components module 291, an automatic/interactive routing of traces module 296, and possibly other modules. Example operations of the various modules are described herein, however it will be appreciated that functionality may be transferred among modules and regrouped to suit specific embodiments. Furthermore, interaction between the modules can be altered and sequenced as necessary for specific embodiments.

The schematic import and/or drawing module 297 may receive a circuit schema comprising one or more electronic components in a circuit. The received circuit schema may comprise data describing one or more circuits. The data can be predefined or input by a user. Predefined data may be predefined by the modules 292 or by third party software. The data may include, for example, data identifying the electronic components used in a circuit, the outline/symbol of the electronic components, and the electrical, optical, thermal and other connections between the electronic components.

The schematic import and/or drawing module 297 may furthermore receive input, for example in the form of data contained in the circuit schema, or in received user input, a template or knowledge base as described below, defining a number of surfaces and/or layers on which to map a received circuit schema. Where a circuit is mapped to a single surface, the mapping operation is straightforward. Where a circuit is mapped to a multiple surfaces and/or using multilayer boards, pins or pin extensions may be placed as vias between layers/surfaces of a board, and may be used to connect between those portions of a circuit mapped different layers/surfaces.

The component patterns import and/or drawing module 298 provides data describing electronic components. In one embodiment, this data may be used for associating a group of circuit points with terminals of each electronic component in a circuit. The number and spacing of terminals for each electronic component may be determined, and corresponding groups of circuit points may be associated therewith. For example, different electronic components have different number and spacing of terminals, as shown in FIG. 25-FIG. 29, and so appropriate number and spacing of corresponding circuit points are needed to connect the various SpinConnectors to the component terminals. Module 298 may furthermore perform functions such as looking up visual representations of electronic components for display, and computing the size and position of electronic components associated with a circuit. Representations of the electronic components may be defined by a user or predefined. For example, in one embodiment, module 298 may access a database of predefined graphics representations of electronic components. In another embodiment, module 298 may support interactive user modification of electronic component properties.

The circuit layout parameters module 293 may receive circuit parameters, wherein the circuit parameters are received from one or more of a circuit parameters template and user defined circuit parameters. Circuit layout parameters may comprise, for example, required distances between the components, minimum widths of the traces, minimum distances between the traces, whether a circuit is to be single sided or multiple sided, the size and shape of a perforated board, whether conductive pads or receptacles are to be used as circuit points, and other parameters as useful to particular embodiments.

The circuit layout parameters module 293 may include appropriate user interface elements to allow specification of the parameters of the traces and perforated board layout. In embodiments supporting user interaction, one or more user selectable modes may be provided. In an expert mode, a user may specify the parameters of the traces and board layout directly. In a template mode, a user may choose from predefined templates according to predefined criteria. In a knowledge base mode, a user may insert functional parameters of a circuit, (such as, a power supply's voltage and current, an input voltage, a frequency of operation, a manufacturing cost, and so forth) and the circuit layout parameters module 293 may automatically determine layout parameters from a stored knowledge base.

Given a schematic, the representations of the components, and the circuit layout parameters, the SpinBoard design module 294 may initially provide a generic distribution defining circuit point positions, such as an equilateral triangle based grid distribution, quadrilateral grid distribution, or other distribution as provided herein.

The automatic/interactive positioning of components module 291 may find an optimal placement of the electronic components using the provided distribution, thereby positioning and orienting the groups of pins associated with the various electronic components on a grid. Positioning an element refers to placing the element at a particular location, while orienting an element refers to placing it at a particular rotational angle. Some embodiments may support circuit points sharing, in which a single circuit points is associated with several components. In such embodiments, a single circuit points may be included in multiple different groups of circuit points, where the different groups are associated with different electronic components.

The automatic/interactive routing of traces module 296 may determine the optimal routing of the traces given a placement of the electronic components, thus positioning and orienting one or more plates to define a trace between circuit points according to the circuit schema, wherein the plates form conductive connections between the circuit points, and wherein the plates comprise one or more of conductive pads and receptacles at the circuit points.

Once the electronic components and traces are positioned and oriented, an output layout may be interactively adjusted by a user. Modules 291 and 296 may reorient or reposition the electronic components and pin connectors in response to a user input. The user input may comprise, for example, one or more of a command to automatically reorient or reposition the electronic components and pin connectors, a user reorientation or repositioning of one or more specific electronic components and pin connectors, and a modification of the circuit parameters. In some embodiments, the user may for example adjust the positioning and/or orientation of the components and/or of traces, and may let the automatic/interactive routing of traces module 296 find another optimal routing, and the automatic/interactive positioning of components module 291 find an another optimal placement of electronic components, followed by re-routing the traces with module 296. In some embodiments, an electronic component may be repositioned or reoriented by repositioning or reorienting a subset of a group of circuit points associated with the electronic component, while those circuit points not in the subset are not repositioned and/or or reoriented. For example, where an electronic component is rotated while leaving one circuit points at a same position, that one circuit points is not repositioned while a subset of the circuit points associated with the electronic component are repositioned.

The modules 291 and 296 can account for the aperture layout of a particular SpinBoard assembly, and can furthermore provide for automatically rotating a circuit on a given layout, reorienting and re-routing electronic components and SpinConnectors. In particular, as described above in the discussion of FIG. 1, a triangle-based aperture layout of FIG. 1 allows for more circuit design options than a quadrilateral layout such as FIG. 2. The modules 291 and 296 can exploit the additional design options. For a quadrilateral layout, electronic component and/or SpinConnector angle adjustments at 45 degree increments can be supported. For a triangle based layout, electronic component and/or SpinConnector angle adjustments at 30 degree increments can be supported.

Once the positioning of the components and the traces are defined, the SpinConnector design module 295 may automatically and/or interactively define the SpinConnectors for the circuit. Accordingly, the SpinBoard design module 294 may provide an outline of a perforated board and a distribution of the apertures for the SpinConnectors. The result is generation of an circuit assembly description 290 defining a circuit and comprising positions and orientations of the electronic components and pin connectors on a grid.

The SpinConnector design module 295 may identify information pertaining to the SpinConnectors, and include this information in the assembly description 290. For example, a circuit point may be identified as a conductive pad circuit point or a receptacle circuit point. This may be done automatically, for example based on an electronic component terminal type, or may be according to circuit parameters described above, or may be received interactively from a user through a user interface. Similarly, properties of receptacle circuit points may be identified. For example, some receptacles may require insertion of a pin, while others may require insertion of a terminal, and furthermore a receptacle may be identified as including (or not including) a pin extension disposed underneath the receptacle. A type of pin for insertion at a receptacle, such as a pin comprising an internal cavity, conductive pad, or jack, or a short pin or specific type of multilayer-adapted pin may be identified. The pin type identification may be included in the circuit assembly description. Still further, pin extension types, pin extension properties, and positions of pin extensions may be identified and included in the circuit assembly description.

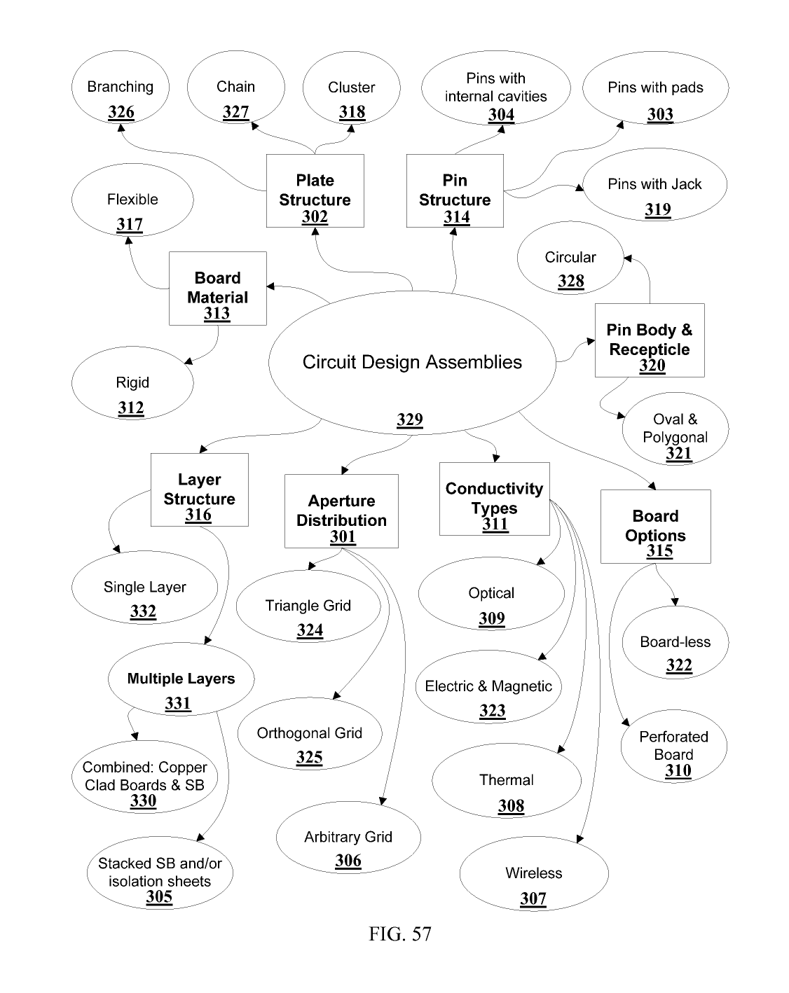

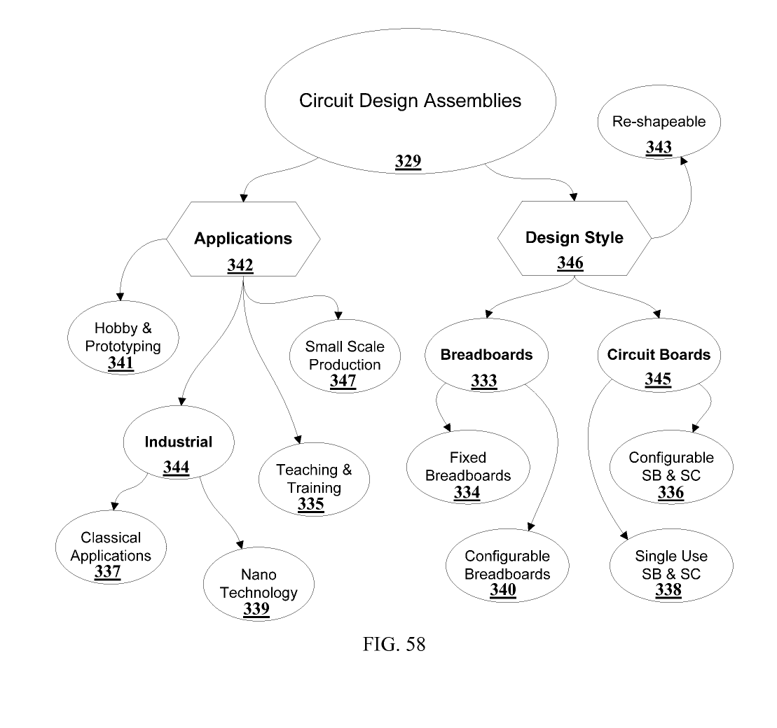

FIG. 57 illustrates an overview of various aspects and options for Circuit Design Assemblies 329 disclosed herein. FIG. 57 provides examples of material described herein in detail, and is intended to summarize but not limit optional configuration characteristics.

Various example board options 315 are disclosed. Board-less assemblies 322 are also referred to herein as SpinConnector assemblies. Perforated board assemblies 310 are also referred to herein as SpinBoard assemblies. SpinBoard assemblies 310 may comprise all the elements of a SpinConnector assembly 322, plus a perforated board. In a SpinBoard assembly 310 SpinConnectors are populating some or all of the apertures of a perforated board.

In some embodiments, board-less assemblies 322 may allow for reshapeable circuits, supporting adjustment of the shape of an assembled circuit and its traces. Such adjustment may furthermore optionally be made without disconnecting electronic components, pins or plates, and optionally without disconnecting a circuit from a power supply—e.g. while a circuit is running. FIG. 36A and FIG. 36C each illustrate a same SpinConnector assembly of the circuit shown in FIG. 30. The assembly of FIG. 36A has been realigned by articulating the joints to obtain the shape shown in FIG. 36C. SpinConnector assemblies can be used in reshapeable applications, as described herein.

Various example board material options 313 are disclosed. In SpinBoard assemblies such as 310, the perforated board material 313 can for example be rigid 312 or flexible 317. The perforated board material can also have other properties such as being opaque or transparent, arbitrarily shaped, planar or non-planar, arbitrary thickness, and layered, with different layers being conductive, non-conductive, or partially conductive depending on the embodiment. Thin perforated board embodiments, less than one millimeter thick, may have advantages in producing very small circuits and for example in embodiments in which the perforated board is flexible, allowing for deformation of the perforated board into desired shapes.

Various example layer structure options 316 are disclosed. The perforated board may be made for example in single layer 332 or multilayer 331 embodiments. Multilayer perforated boards 331 may comprise for example stacked perforated boards and/or isolation sheets 305, and combinations of conductive or non-conductive layers including copper clad boards 330.

Various aperture distribution options 301 are disclosed. Aperture distributions may include, for example, triangle-based grid distributions 324, quadrilateral grid distributions 325 and arbitrary grid distributions 306. Arbitrary grid distributions 306 may include, for example, subsets of the apertures of triangle-based, quadrilateral, or other distribution types. Arbitrary grid 306 may include any aperture distribution, whether in a regular grid pattern, a custom design, or otherwise.

Various pin structure options 314 are disclosed. Pin structures 314 may comprise for example pins with internal cavities 304 that may for example allow insertion of the terminals of electronic components and optionally provide for a friction-based contact and conductivity therewith; pins with pads 303 that may for example allow for soldering electronic component terminals; and pins with jack extensions 319 that may for example allow the pins to be inserted in appropriate connectors of electronic components. In some embodiments, pins with internal cavities 304 and/or jack extensions 319 also allow to solder the terminals and/or pads of electronic components to the pin.

Various plate structure options 302 are disclosed. As disclosed herein, the plates of SpinConnectors serve as bridging elements between pins, and may form traces of electronic circuits. The plate structures 302 may be designed for example in cluster 318, chain 327, or branching 326 configurations.

Various SpinConnector conductivity types 311 are disclosed. A SpinConnector may comprise a conductive pin optionally inserted into a pin receptacle of a conductive plate. In some embodiments, SpinConnectors comprising pins with plate structures as one body are also possible. The conductivity types 311 between the pins, the plates, and electronic components may comprise for example one or more of electrical and/or magnetic 323, thermal 308, optical 309, magnetic, and wireless 307. In some embodiments, electronic components may also be in direct conductive contact with, and or attached to, conductive plates. Furthermore, in some embodiments non-conductive pins and/or plates can be employed, as described in this document.

Various pin body and pin receptacle types 320 are disclosed. Pin body and pin receptacle types 320 may include for example circular structures 328 and oval/polygonal structures 321. A round shaped circumference allows for pin connector joints with no restriction on articulation angles. In some embodiments, an oval/polygonal shaped pin and/or pin receptacle 321 allows restriction of allowable articulation angles.

FIG. 58 illustrates an overview of various applications 342 and design styles 346 for circuit design assemblies 329 disclosed herein. Assemblies 329 comprise SpinBoard and SpinConnector assemblies as disclosed herein. FIG. 58 is intended to summarize but not limit the applications and design styles.

Various example design styles 346 include sets of properties for certain arrangements of assemblies 329. Design styles may include, for example, reshapeable designs 343, breadboard designs 333 and circuit board designs 345. Those properties not included in a particular design style may be according to any variety described herein. For example, any of the illustrated example design styles may comprise non-planar and/or flexible perforated board properties such as illustrated in FIG. 40. Furthermore, circuits with any desired properties may be built on assemblies 329 according to any design style. For example, a configurable LED bulb circuit may be built on assemblies 329 according to any design style.

Reshapeable designs 343 include assemblies 329 that do not comprise a perforated board. These are also referred to herein as SpinConnector assemblies 322. For example, the circuit of FIG. 36C is a reshaped version of the circuit in FIG. 36A.

Breadboard designs 333 include assemblies 329 which are generally in configurations similar to FIG. 51-FIG. 55. These may be further grouped into fixed breadboard designs 334 and configurable breadboard designs 340. Fixed breadboard designs 334 do not allow repositioning or reorientation of SpinConnectors, while configurable breadboard designs 340 allow repositioning and/or reorientation of SpinConnectors.

Circuit board designs 345 include assemblies 329 which are generally in configurations similar to FIG. 34-FIG. 37, and FIG. 39-FIG. 46. Circuit board designs 345 may be further grouped into reusable designs 336 and single-use designs 338. Reusable designs 336 may include assemblies 329 in configurations similar to FIG. 34, FIG. 35, FIG. 37, and FIG. 39-FIG. 45, while single-use designs 338 may include assemblies 329 in configurations similar to FIG. 46.

Any of the designs may be sold as a kit including a plurality of elements for use with the kit. An example kit may comprise a perforated board, SpinConnectors of several predefined connector types with dimensions appropriate for use with the board, and a plurality of electronic components with dimensions appropriate for use with the board and SpinConnectors or Where the types of circuits that will likely be built with the kit are known, the numbers and types of SpinConnectors that are provided, and the properties of the SpinConnectors (such as max current, max pin receptacles, etc.) may be selected accordingly and included in the kit.

Sockets may be advantageously included in the kit. Sockets are an electronic component designed to attach to a perforated board in a particular orientation, and designed to receive one or more additional electronic components. For example, a socket may receive an integrated circuit with a terminal structure that may not easily connect to a perforated board (or SpinConnectors disposed on such perforated board) by itself. Socket types include those designed to receive integrated circuit leads (terminals), and no-lead sockets such as Dual Flat No-Lead Package (DFN) and Quad Flat No-Lead Package (QFN) type sockets.

Various example applications 342 of assemblies 329 are disclosed. Example applications 342 include hobby and prototyping applications 341, teaching and training applications 335, small scale applications 347, and industrial applications 344. In general, assemblies with any desired properties may be produced in any of the listed applications. For example, both planar and non-planar assemblies, single layer and multilayer assemblies, and configurable LED bulb assemblies may be built according to any of the illustrated applications 341, 335, 347, and 344.

Hobby and prototyping applications 341 and teaching and training applications 335 allow for building circuits which are not necessarily mass produced. Such applications may be for experimental, prototyping, home-use, teaching, training, and educational type purposes. Assemblies 329 allow for building professional-quality circuitry with a minimum of interference between the various circuit traces and components, and circuits which are closer to likely “final” circuit embodiments that are substantially ready for mass production or other final arrangement.

Teaching and training applications 335 may be optimized for different levels. For example, fixed breadboard design styles may be used at a first level, in which the existing SpinConnector pattern guides student choices, challenging the student to think according to the pattern. Moreover, triangle based aperture layouts (or other non-quadrilateral layouts) may allow the student to design circuits in modes that allow more freedom than quadrilateral layouts. At a subsequent student level, configurable breadboard design styles can allow the student freedom to design circuits according to any desired arrangement. At a subsequent student level, reusable circuit board design styles may be used to allow wider design options, optionally including wider varieties of SpinConnector types and perforated board types as well, allowing multiple connection types such as friction fit as well as soldering, and more SpinConnector plate lengths and configurations. At a subsequent student level, single-use type configurations may be provided, wherein the single-use configurations are optimized for student needs, such as, for example, providing perforated boards with only the needed apertures, providing SpinConnectors and electronic components as needed for the student's particular purposes.

Small scale electronic circuit design applications 347 may be optimized for small scale production, in which numbers of circuits to be produced are more than in hobby and prototyping applications 341, but typically less than industrial applications 344. Reusable circuit board design styles and single-use circuit board design styles may be particularly suited for applications 347 in some embodiments.

Industrial electronic circuit design applications 344 may be optimized for large-scale production. Assemblies 329 may be adapted to serve as any of the many circuits that are in use in a wide a wide variety of classical applications 337 today. Classical applications 337 include for example consumer electronics such as home appliances, toys, and computers, medical equipment, industrial equipment, vehicle electronics, low and high power electronics, and so forth. Applications employing nanotechnology 339 allow for creating fine and miniature electronic circuit boards using assemblies 329. Such electronic circuit assemblies could be used in any technological field, including bio-technology, compact devices, and so forth. Nanotechnology based assemblies 329 can be situated in between the microscopic scale of integrated circuits and classical circuit boards.

Any of the various design styles 346 may be used in any of the applications 342. For example, in hobby and prototyping applications 341, breadboard design styles 333 provide advantages in easily configuring and reconfiguring prototype circuits. Once circuit designs are validated through prototyping, circuit board design styles 345 become advantageous in building finalized circuits. Properties of an assembly 329 in a first design style, such as a breadboard design style 333 may be carried over to subsequent design styles (e.g. circuit board design styles 345). For example, multilayer breadboard designs may be carried over to multilayer circuit-board designs when a prototyped circuit is built on the subsequent design.

While various embodiments have been disclosed herein, other aspects and embodiments will be apparent to those skilled in art.

1. A pin and plate connector assembly for building a circuit, comprising:
a plate of conductive material, the plate comprising:
a bridge of conductive material;
at least one conductive receptacle in conductive contact with the bridge, the receptacle adapted to make conductive contact with a sidewall of a pin insertable into the receptacle; and
at least one pin, the pin insertable into the receptacle to form a conductive connection between a pin sidewall and the plate, and the pin comprising one or more of an interior cavity, a conductive pad, or a conductive jack;
the pin and plate connector structure forming at least a portion of a trace for the circuit.

2. The pin and plate connector assembly of claim 1, further comprising a perforated board on which the pin and plate connector structure is mounted, wherein the at least one pin is inserted into a perforated board aperture.

3. The pin and plate connector assembly of claim 1, wherein the pin and plate connector structure is conductively couplable to a second pin and plate connector structure to form a connector chain which forms at least a portion of the circuit.

4. The pin and plate connector assembly of claim 1, wherein the receptacle is in an oval or polygon shape.

5. The pin and plate connector assembly of claim 4, wherein the pin is in a same oval or polygon shape as the receptacle so that a limited set of predefined orientations exist between the pin and the receptacle.

6. The pin and plate connector assembly of claim 1, wherein the plate comprises a cluster, chain, or branch plate configuration.

7. The pin and plate connector assembly of claim 1, wherein bridge comprises an insulated bridge portion.

8. A circuit design assembly, comprising:
a perforated board comprising a plurality of apertures, wherein the apertures are positioned to define one or more triangles;
at least one plate comprising a receptacle;
at least one pin insertable into an aperture and the receptacle, wherein the pin inserted into the receptacle allows definition of a circuit point or a joint for a circuit trace; and
wherein the plate and pin combine to make conductive contact with one another and to form a connector, wherein the connector forms at least a portion of the circuit trace.

9. The circuit design assembly of claim 8, wherein the at least one pin includes one or more of an interior cavity, a conductive pad, or a conductive jack for conductive contact with an electronic component.

10. The circuit design assembly of claim 8, wherein the circuit design assembly allows building a user-configurable circuit.

11. The circuit design assembly of claim 10, further comprising at least one Light Emitting Diode (LED) conductively couplable to the connector for building a user-configured LED bulb.

12. The circuit design assembly of claim 8, further comprising a predefined circuit comprising the connector, the predefined circuit disposed on the perforated board.

13. The circuit design assembly of claim 8, wherein the at least one plate includes one or more of a conductive pad, a conductive jack, and a receptacle adapted for conductive contact with an electronic component.

14. The circuit design assembly of claim 8, wherein a distance between the receptacle and circuit point disposed on the plate equals the length of a side of the one or more triangles, the circuit comprising a receptacle, a conductive pad or a jack.

15. The circuit design assembly of claim 8, wherein the at least one plate comprises a cluster, chain, or branch plate configuration.

16. The circuit design assembly of claim 8, wherein the at least one plate comprises an insulated bridge portion.

17. The circuit design assembly of claim 8, wherein the at least one pin is insertable into receptacles corresponding to two or more plates.

18. The circuit design assembly of claim 8, wherein the at least one pin is shorter than a length of the aperture.

19. The circuit design assembly of claim 8, further comprising an isolation sheet.

20. The circuit design assembly of claim 8, further comprising a plurality of connectors affixed to the perforated board to form a breadboard with predefined conductive connections between the apertures.

21. The circuit design assembly of claim 8, wherein the perforated board comprises a subset of all possible apertures, given a grid pattern defining a plurality circuit point positions for the perforated board.

22. The circuit design assembly of claim 8, wherein the perforated board is made of one or more of a flexible material, multiple layers, a transparent material, and a material that is less than one millimeter thick.

23. A circuit design assembly, comprising:
a board comprising a triangular grid pattern, the triangular grid pattern defining a plurality of circuit point positions;
at least one plate comprising one or more of a circuit point and a pin extension;
wherein a plurality circuit points, a plurality of pin extensions, or a combination of a circuit point and a pin extension aligns with circuit point positions defined by the triangular grid pattern.

24. The circuit design assembly of claim 23, wherein the board comprises at least one aperture at a circuit point position aligned with a circuit point or pin extension on the plate.

25. The circuit design assembly of claim 23, wherein a circuit point comprises a receptacle, a conductive pad, or a conductive jack.

26. The circuit design assembly of claim 25, further comprising a pin insertable into the receptacle.

27. The circuit design assembly of claim 26, wherein the pin is configured to make conductive contact with the at least one plate and a second plate.

28. The circuit design assembly of claim 23, wherein a pin extension is insertable into a receptacle disposed on a second plate.

29. The circuit design assembly of claim 23, wherein the at least one plate is disposed on a first surface of the board, and further comprising a second plate on a second surface different from the first surface.

30. The circuit design assembly of claim 23, wherein the board comprises multiple layers.

31. The circuit design assembly of claim 23, wherein the circuit design assembly allows building a user-configurable circuit.

32. The circuit design assembly of claim 23, further comprising a predefined circuit comprising the at least one plate, the predefined circuit disposed on the board.

33. A method for generating a circuit assembly description defining positions and orientations of plates and electronic components connected in a circuit, the method comprising:
receiving a circuit schema comprising one or more electronic components in a circuit;
associating a group of circuit points with terminals of an electronic component;
positioning and orienting the group of circuit points on a grid;
positioning and orienting one or more plates to define a trace between circuit points according to the circuit schema, wherein the plates form conductive connections between the circuit points, and wherein the plates comprise one or more of conductive pads, receptacles or jacks at the circuit points; and
generating the circuit assembly description defining the circuit and comprising positions and orientations of the electronic components, circuit points, and plates on the grid.

34. The method of claim 33, further comprising receiving circuit parameters, wherein the circuit parameters are received from one or more of a circuit parameters template, a user input, and a knowledge base providing circuit parameters according to required functional parameters.

35. The method of claim 34, further comprising reorienting or repositioning the electronic components and plates in response to a user input, the user input comprising one or more of a command to automatically reorient or reposition the electronic components and plates, a user reorientation or repositioning of one or more specific electronic components and plates, and a modification of the circuit parameters.

36. The method of claim 33, wherein a single circuit point is associated with several electronic components.

37. The method of claim 33, further comprising repositioning or reorienting an electronic component by repositioning or reorienting a subset of a group of circuit points associated with the electronic component.

38. The method of claim 33, wherein the grid comprises a triangle based grid.

39. The method of claim 33, further comprising identifying at least one circuit point as a conductive pad circuit point, a receptacle circuit point, or a jack circuit point, and including a circuit point identification in the circuit assembly description.

40. The method of claim 39, wherein the identifying at least one circuit point comprises receiving a user identification of the at least one circuit point.

41. The method of claim 33, further comprising:
identifying a circuit point requiring a pin;
identifying a type of pin or a type of pin extension for the circuit point; and
including a pin type identification or pin extension type identification in the circuit assembly description.

42. The method of claim 33, further comprising mapping the circuit schema onto two or more surfaces of a circuit board.

43. A process for manufacturing a circuit board, comprising:
preparing a set of plates corresponding to circuit traces, each plate comprising at least one circuit point, and each circuit point comprising a conductive pad, a receptacle or a jack;
affixing the plates to a non-conductive portion of a board surface.

44. The process for manufacturing a circuit board of claim 43, further comprising inserting a pin into a receptacle and corresponding aperture on the circuit board.

45. The process for manufacturing a circuit board of claim 43, at least one plate comprising a pin extension corresponding to a predefined aperture on the board surface.

46. The process for manufacturing a circuit board of claim 43, wherein the affixing the plates is performed in a predefined assembly line sequence.
